(19) United States
(12) Patent Application Publication
(10) Pub. No.: US 2024/0128146 A1
(43) Pub. Date: Apr. 18, 2024

(54) SEMICONDUCTOR PACKAGE FOR ENHANCED COOLING

(71) Applicants: ND-HI TECHNOLOGIES LAB, INC., TAIPEI CITY (TW); ETRON TECHNOLOGY, INC., HSINCHU (TW)

(72) Inventors: HO-MING TONG, TAIPEI CITY (TW); CHAO-CHUN LU, HSINCHU (TW)

(21) Appl. No.: 18/474,250

(22) Filed: Sep. 26, 2023

Related U.S. Application Data
(60) Provisional application No. 63/409,854, filed on Sep. 26, 2022.
(60) Provisional application No. 63/432,414, filed on Dec. 14, 2022.
(60) Provisional application No. 63/583,008, filed on Sep. 15, 2023.

(51) Int. Cl. H01L 23/367; H01L 23/00; H01L 23/528; H01L 25/065; H10B 80/00

(52) U.S. Cl. CPC H01L 23/3672; H01L 23/5286; H01L 24/08; H01L 25/0652; H10B 80/00; H01L 2224/08225

(57) ABSTRACT

The present application discloses a semiconductor package which includes a processor die powered by either a front-side or a backside power delivery network, a plurality of memory dies and control dies stacked over the processor die, a plurality of high-thermal-conductivity (HTC) interconnects formed on, located between and/or placed side-by-side with the dies, a HTC substrate carrying all the dies, a HTC structural member, and a HTC heat spreader/heatsink with the dies and the HTC heat spreader thermally coupled to other HTC components in the semiconductor package. The semiconductor components can be configured to go beyond the traditional single-sided interconnection and cooling topologies to enable dual-or multi-sided cooling, power supply, and signaling.

### PRIORITY CLAIM AND CROSS-REFERENCE

This application claims the benefit of prior-filed U.S. provisional application No. 63/409,854, filed on Sep. 26, 2022, prior-filed U.S. provisional application No. 63/432,414, filed on Dec. 14, 2022, and prior-filed U.S. provisional application No. 63/583,008, filed on Sep. 15, 2023 incorporates by reference herein in their entirety.

### FIELD

The present disclosure relates to a semiconductor package, and more particularly, to a semiconductor package capable of enhancing heat dissipation for 3D ICs.

### BACKGROUND

2D geometrical scaling of conventional transistors is fast approaching “red brick wall” despite most recent evolutions attributable to the great feats of engineering and material science involving extremely complex multiple-step lithographic patterning, new strain enhancing materials and metal oxide gate. 3D IC (3D integrated circuit) integration represents a radical departure from traditional 2D IC and 2D package integration by vertical stacking of ICs and/or transistor layers on a single interposer or substrate to provide extremely dense ICs. 3D ICs have been recognized as a next generation semiconductor technology, which has the advantage of high performance, low power consumption, small physical size and high integration density. 3D ICs provide a path to continue to meet the performance/cost demands of next generation devices while remaining at more relaxed gate lengths with less process complexity.

For high-end applications such as high performance computing (HPC), data centers, artificial intelligence (AI) and smart handhelds, advanced SiPs (system-in-a-packages) containing a plurality of active dies with processor and memory in particular are usually adopted to increase the computation power within smaller form factors. Advanced SiPs described herein include 2.5D IC as shown in FIG. 1A, fan-out SiP as shown in FIG. 1B, embedded SiP as shown in FIG. 1C, silicon photonics as show in FIGS. 1D and 3D IC as shown in FIG. 1E.

In FIG. 1A, a 2.5D IC structure 90 includes a laminate substrate 901 supporting a silicon interposer 902 through a plurality of solder connections 903. The silicon interposer 902 which is commonly used in 2.5D IC packaging and contains through silicon vias (TSVs) 904 can be used as a platform to bridge the fine-L/S/pitch capability gap between the laminate substrate 901 and IC blocks covering a 3D IC such as a high-bandwidth-memory (HBM) dynamic random-access memory (DRAM) stack, i.e., the memory structure 905 and a processor IC 907 in FIG. 1A. The silicon interposer 902 can possess passive and/or active IC functions per application. Besides memory devices (e.g., the memory structure 905) and logic devices (e.g., the processor 907), a wide variety of other types of electronic components including other types of active ICs (e.g., analog and mixed signal devices), MEMS (micro-electro-mechanical system) devices, and passive devices can be mounted on the silicon interposer 902 produced by wafer-level processes. These electronic components can be arranged in the form of 2D IC via side-by-side placement of dies, 2.5D IC containing a plurality of 3D memory structure 905 mounted side-by-side with the processor on the interposer (FIG. 1A), or 3D IC package with the memory structure 905 mounted on top of the processor which, in turn, is mounted on the interposer. For instance, the memory structure 905 in FIG. 1A can be a HBM DRAM stack which includes a plurality of DRAM dies 905a vertically stacked over a base control die 905b through copper pillar micro-bumps now or copper hybrid bonding layers in the future as the process matures. As shown in FIG. 1A, the laminate substrate 901 upon which the silicon interposer 902 is bonded using micro-bumps or solder bumps can be bonded to a printed circuit board, PCB (not shown in the figure) through a plurality of ball grid array (BGA) solder balls 906 underneath the laminate substrate 901.

In FIG. 1B, a fan-out package structure 91 can be adopted with electrical connections on chips, 913a and 913b, fanned-out from the chip's active surfaces to enable placement of external I/Os 903a beyond the confines of the chips. The fan-out package structure 91 which includes one or more semiconductor chips (e.g., chip 913a, and chip 913b) encapsulated in a molding compound allows individual chips to be connected to the fan-out wiring layers or redistribution layers (RDL) 911, and coupled with the solder bumps 903a or alternatively, micro-bumps for connection to a substrate 901, which can be a laminate substrate, an interposer or a fan-out package structure bonded to a next-level substrate (e.g., a PCB) using solder bumps or solder balls 906. Besides the structure shown in FIG. 1B, a wide-variety of other fan-out package structures also exist including structures that contain through-mold vias (TMVs, see FIG. 2) either with appropriate surface finish formed on top of the TMVs exposed at the top molding compound surface or connecting the RDL 911 in FIG. 1B to another RDL formed on top of the molding compound to facilitate subsequent vertical mounting of another electronic component such as memory on top of the fan-out structure. The highest-volume commercialized fan-out packages as depicted in FIG. 2 can be found in smart handheld applications wherein the application processor (AP) die is embedded in the molding compound and a DRAM package is mounted on the fan-out structure.

In FIG. 1C, an embedded SiP 92 includes one or more devices 923 embedded in the laminate substrate 901. The one or more devices 923 can be an embedded silicon interconnect (which can be either a passive device or an active device), an active IC device (e.g., a DC-DC converter) or an embedded passive device such as a capacitor or an inductor. Furthermore, the laminate substrate 901 with the device 923 embedded therein can be further bonded to another laminate substrate or PCB 908 through solder balls 906 or micro-bumps, depending on applications. Embedded SiPs are often implemented in conjunction with advanced SiPs including fan-out structures containing dies embedded in a molding compound (FIG. 1B).

In FIG. 1D, a silicon photonics structure 93 includes a CMOS die 916, a waveguide structure 918 with a modulator 919 and a photodetector 920 embedded within, and an optical fiber 921 coupling optical signal into or out from the waveguide structure 918. A laser diode 917 and the waveguide structure 918 as well as the components coupled to the waveguide structure are integrated over a silicon interposer 914 with TSVs. The silicon interposer 914 produced by wafer-level processes is configured to be mounted on a substrate such as a laminate substrate through a plurality of solder bumps or micro-bumps 903 for external connections.

In FIG. 1E, a 3D IC based structure 94 includes a first die 940 (in bare die form), and second dies 941 (also in bare die form). The first die 940 can be a processor die while the second dies 941 can contain DRAM dies or other types of memory devices such as SRAM. The second dies 941 can be stacked on the first die 940 through various suitable bonding technologies including flip chip and copper hybrid bonding. The 3D IC based structure 94 allows the first die 940 (e.g., the processor die) to access the second dies 941 (e.g., the memory dies) in close proximity with the shortest data transfer times between processor and memory among all advanced SiPs (see FIGS. 1A to 1E and FIG. 2).

Going forward, the number of 3D IC applications will steadily increase. 3D ICs are expected to find broad based utilities in applications such as high-performance computing (HPC) and data centers, AI (artificial intelligence)/ML (machine learning), 5G/6G networks, graphics, smart phones/wearables, automotive and others that demand “extreme,” ultra-high-performance, higher-power-efficiency devices. These devices include CPU (central processing unit), GPU (graphics processing unit), FPGA (field-programmable gate array), ASIC (application specific IC), TPU (tensor processing unit), integrated photonics, AP (application processor for cell phones), and packet buffer/router devices.

To accelerate adoption, 3D IC systems must be architected in a holistic way via IC-package-system co-design which involves the silicon IP, ICs/chiplets and IC package and addresses accompanying power and thermal challenges. In contrast to PPAC (performance, power, area and cost) optimization per “square centimeter” for 2D packaging, IC-package-system co-design for 3D ICs aims to achieve PPAC optimization per “cubic millimeter” wherein the vertical dimension that covers ICs, interposer, IC package substrate, IC package and system printed circuit board (PCB) must now be considered in all tradeoff decisions.

Commercial 3D ICs such as a 3D HBM DRAM memory stack are increasingly being supported by commercial 2.5D ICs (e.g., the 2.5D IC structure 90 shown in FIG. 1A) containing through silicon vias (TSVs) in both active dies and in the silicon interposer. With appropriate thermal solutions, 3D ICs can ultimately enable memory on memory, memory over logic, logic over logic using interconnect technologies such as TSV, RDL containing interconnect wiring and micro-vias, flip chip bonding using copper pillar micro-bumps or solder bumps, and the emerging copper hybrid bonding first proven by Sony for complementary metal-oxide semiconductor (CMOS) image sensors for inter-die communication.

3D ICs allows for vertical stacking of heterogeneous dies from different manufacturing processes and nodes, chip reuse and chiplets-in-SiP for high-performance applications already pushing the limits of a single die at the most advanced node. 3D IC integration can proceed via 3D monolithic integration, and/or vertical integration of disparate bare dies (as in the case of HBM DRAM stacks) or dies embedded in different package layers.

3D monolithic integration involves typically vertical integration of multiple active silicon layers with vertical interconnects between the layers. It is still in the early development stage and is not widely deployed yet. Recently, a “cache-on-central processing unit (CPU)” 3D IC structure has been demonstrated and commercialized using copper hybrid bonding. Today, HBM DRAM stacks, each of which created by vertically integrating a number of DRAM dies on a control IC, represent the highest volume commercial 3D ICs today. 3D ICs are ideal for applications requiring packing more transistors in a given device footprint such as mobile system-on-chip, SoC (e.g., the AP in FIG. 2) for mobile applications and for other applications already pushing the limits of a single die at the most advanced node for applications such as HPC, data centers and AI.

Mobile devices (e.g., smart phones) present special thermal management challenges due to small areas to dissipate the heat, small available spaces to implement heat spreading solutions, and heat generation in mobile devices is limited by relatively low maximum allowed case temperature of typically between 44° C. and 50° C.

FIG. 2 shows a current smart mobile application based on a package-on-package (PoP) structure 96. As shown in FIG. 2, a DRAM package 931 is stacked on an application processor (AP) package 932 in the PoP structure. The DRAM package 931 includes DRAM dies 9311 stacked on a laminate substrate 9312, a molding layer 9313 (e.g., a molding compound) encapsulating the DRAM dies 9311, and solder balls 9314 formed on the laminate substrate 9312 which is vertically bonded to the AP package 932. The AP package 932 includes an AP die 9321, a mold layer 9322 encapsulating the AP die 9321, a plurality of TMVs 9323 formed in the mold layer 9322 and coupled to the solder balls 9314 of the DRAM package 931, and a RDL 9324 formed on the AP die 9321 and the mold layer 9322, and solder balls 9325 formed on the RDL 9324. Furthermore, the PoP structure 96 is mounted on a PCB 933 through the solder balls 9325, and a heat spreader 934 is disposed over the DRAM package 931 with a thermal interface material (TIM) 9381. The PoP structure 96 and the PCB 933 are disposed inside the case 935 of the smart mobile device under a display panel 936. To reduce the interference, a shield 937 can be disposed on the heat spreader 934 with a thermal interface material (TIM) 9382 and under the display panel 936 so as to protect the PoP structure 96. Furthermore, a gap filler 939 may be added between the PCB 933 and the case 935 to fill the space in between the PCB 933 and the shield/case.

In the smart mobile device structure shown in FIG. 2, the heat generated by the AP die 9321 is dissipated primarily through the molded stacked-die DRAM BGA package 931 mounted on top of the AP package 932 to the heat spreader 934 and then to the case 935.

There exists a higher thermal resistance from the hot spots of the AP die 9321 to the surface of the case 935 (since the molding compounds used in the molding layers 9313 and 9322 are practically thermal insulators) compared to the heat removal from the surface of the case 935 to the ambient by natural convention and radiation (which depends primarily on the surface areas of the mobile device). This limits the maximum AP power the semiconductor package in FIG. 2 can entertain in order to control the case temperature to under its maximum allowed temperature, typically between 44° C. and 50° C. For mobile devices where space is premium and there is typically no space for fans and finned heatsinks, heat spreading from the AP package to the case as shown in FIG. 2 is the primary means of heat dissipation.

Driven by the continuing explosive growth of applications and data traffic, AP powers for mobile devices are expected to increase, thereby seriously challenging the cooling limits of the PoP package structure shown in FIG. 2. Moreover, higher data traffic requires higher memory capacities to communicate with the more powerful, higher-power AP dies. To increase the memory capacity while improving the heat dissipation efficiency from the fan-out AP package to the case, one can stack more DRAM dies (containing a control IC as needed on the bottom of the DRAM dies) in bare die form in the vertical or package thickness direction on the AP package, or better yet, on the bare AP die (in 3D IC) or a high-thermal-conductivity interposer (in 2.5D IC) as opposed to stacking the molded DRAM laminate package (as shown in FIG. 2) with the understanding that the laminate substrate used in the DRAM package and the molding compounds used in both the DRAM package and fan-out AP package are poor thermal conductors compared to the silicon substrate in bare dies.

3D DRAM stacks (e.g., based on wide—I/O DRAM dies for mobile devices or HBM DRAM dies for HPC, data center and AI applications) offer lower power, higher bandwidth and higher density advantages compared to 2D DRAM packages mounted on the PCB. In a 3D DRAM stack, the power per unit area can increase as a result of more-die stacking (with neighboring dies in the vertical stack heating each other) and the bottom and middle tiers DRAM typically have limited heat dissipation paths compared to dies on top of them which are closer to the heat spreader or a vapor chamber and heatsink in the case of air cooling used in mobile devices. Both factors can contribute to overheating of 3D devices (compared to 2D memories) with the hottest tiers at the bottom and the cooler tiers at the top. High temperatures in a DRAM can result in reduced performance and efficiency, especially when dynamic thermal management schemes are used to throttle DRAM bandwidth whenever temperature gets too high. Overheating can also cause the devices to be stalled, i.e., prevented from being accessed, as well as reliability issues. All electronic devices function reliably within a particular temperature range. As more DRAM dies are stacked vertically on a processor, new thermal solutions are needed to mitigate the overheating effects associated with lower-tier DRAM dies and the control IC particularly when they are stacked directly on top of a higher-power processor such as the AP die or a processor in 3D IC, which aggravates the aforementioned overheating effects.

With the overheating effects resolved using new thermal management solutions to be disclosed herein, placing a plurality of DRAM dies (and control ICs) directly on top of the processor, whether it be the AP die or the processor for HPC, data center and AI applications, helps to not only increase the memory capacities but also reduce the compute and memory bandwidth gaps. Going forward, the rate of advancement in processor speed will continue to exceed the rate of advancement in DRAM memory speed. The exponent for microprocessors is substantially larger than that for DRAMs although each is improving exponentially. As shown in FIG. 3 (cited from Riselab at UC Berkeley), the interconnect bandwidth between processor and memory lags behind processor performance gains. This creates the “memory wall” effect which has prevented processor performance from being fully exploited. Memory latency and bandwidth will continue to limit system performance with sustained (streaming) memory bandwidth falling behind peak FLOP rates as shown in FIG. 3 for high-end applications such as HPC, data centers and AI. This imbalance which also applies to application processors has created a significant bottleneck that continues to grow larger each year while the industry continues to demand even more computing performance.

Today, 2.5D ICs and 3D ICs such as the HBM DRAM stacks or similarly wide-I/O DRAM stacks for mobile devices adopt single-sided packaging topologies containing single-sided cooling from the top side of the top ICs and single-sided areal electrical interconnects for power supply and signaling, e.g., from the bottom-side of the bottom IC, e.g., the control die in FIG. 1A, to dies above, one-die-at-a-time. These packaging topologies are created, for example, by the aforementioned interconnect technologies including flip chip assembly, TSV and RDL. In powering 3D ICs, designers must consider all stacked die/package layers in designing the power delivery network with the die on top gets its power from the die below and the bottom die from the 2.5D interposer (FIG. 1A) or the laminate substrate (FIGS. 1B and 2). The single-sided interconnects and single-sided cooling are not scalable since the 3D IC footprint (e.g., see FIG. 1E on 3D IC, or the HBM stack in FIG. 1A on 2.5D IC) is invariant to increasing numbers of dies in the stack. The single-sided electrical interconnects and cooling impose a severe constraint on PPAC optimization by designers of 3D ICs to come up with optimal design solutions.

### SUMMARY

One aspect of the present disclosure provides a semiconductor package. The semiconductor package includes a first die and a first supporter. The first die has a front side and a backside. The first supporter is disposed immediately under the first die and thermally coupled to the first die. The thermal conductivity of the first supporter is greater than the thermal conductivity of the first die.

Another aspect of the present disclosure provides a semiconductor package allowing for dual-sided or multi-sided power supply and signaling, as well as dual-sided or multi-sided cooling. The semiconductor package includes a processor die, a plurality of memory dies and control dies or a plurality of 3D memory stacks, a first high thermal conductivity (HTC) structure, and a plurality of other HTC structures. The processor die has a front side and a backside. The first HTC structure is disposed immediately under the processor die and thermally coupled to the processor die. The thermal conductivity of the first HTC structure is greater than the thermal conductivity of the processor die. The memory dies and the control dies are stacked over the processor die. The plurality of other HTC structures are disposed between the processor die and control dies, between adjacent vertically stacked memory dies, placed side-by-side with the dies, and/or created on the dies as integral parts of these dies in the semiconductor structure. Each of the thermal conductivities of the plurality of other HTC structures is greater than the thermal conductivity of the processor die.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIGS. 1A to 1E each illustrates an advanced SiP structure.

FIG. 2 shows a smart mobile application using a package-on-package structure.

FIG. 3 shows the scaling of bandwidth through different generations of interconnections and memory, as well as peak floating-point operations per second (FLOPS) of processors.

FIG. 4 shows a semiconductor package according to one embodiment of the present disclosure.

FIGS. 5A to 5D show the detailed interface structures in the semiconductor package in FIG. 4.

FIGS. 6A to 6E show manufacturing operations to build the semiconductor package in FIG. 4.

FIG. 7 shows a semiconductor package including a 3D IC structure according to an embodiment of the present disclosure.

FIGS. 8A to 8F show manufacturing operations to build the semiconductor package in FIG. 7 according to an embodiment of the present disclosure.

FIGS. 9A to 9D illustrate a process to create advanced interposers or ICs using a full sized, reconstituted diamond wafer, according to some embodiments of the present disclosure.

FIGS. 10A to 10D illustrate a process to create advanced ICs using a full-sized, reconstituted diamond-based bi-wafer, according to some embodiments of the present disclosure.

FIGS. 11A to 11D illustrate a process to create advanced ICs using a full-sized, reconstituted silicon-diamond-silicon tri-wafer, according to some embodiments of the present disclosure.

FIGS. 12A and 12B illustrate exemplary advanced ICs and advanced interposers that can be created by full-sized diamond based composite wafers, according to an embodiment of the present disclosure.

FIG. 13 shows a semiconductor package including a 3D IC structure, according to another embodiment of the present disclosure.

FIG. 14 shows a semiconductor package including a 3D IC structure, according to another embodiment of the present disclosure.

FIG. 15 shows a semiconductor package including a 3D IC structure, according to another embodiment of the present disclosure.

FIG. 16 shows a semiconductor package including a 3D IC structure, according to another embodiment of the present disclosure.

FIG. 17 shows a semiconductor package including a 3D IC structure, according to another embodiment of the present disclosure.

FIG. 18 shows a semiconductor package including a 2.5D IC structure, according to another embodiment of the present disclosure.

FIG. 19 shows a semiconductor package including a 2.5D IC structure, according to another embodiment of the present disclosure.

FIG. 20 shows a semiconductor package including a 3D IC structure, according to another embodiment of the present disclosure.

FIG. 21 shows a semiconductor package including a 3D IC structure, according to another embodiment of the present disclosure.

FIG. 22 shows a semiconductor package including a 3D IC structure, according to another embodiment of the present disclosure.

FIG. 23 shows a semiconductor package including a 3D IC structure, according to another embodiment of the present disclosure.

FIGS. 24A to 24C provide manufacturing operations to form a processor-diamond combo with a BSPDN, according to some embodiments of the present disclosure.

FIG. 25 provides manufacturing operations to form a thermal isolation layer and/or a thermal spreading layer in the semiconductor package structures, according to some embodiments of the present disclosure.

FIG. 26 shows a semiconductor package including a 3D IC structure, according to another embodiment of the present disclosure.

FIG. 27 shows a semiconductor package including a 3D IC structure, according to another embodiment of the present disclosure.

FIG. 28 shows a semiconductor package including a 2.5D IC structure, according to another embodiment of the present disclosure.

FIG. 29 shows a semiconductor package including a 2.5D IC structure, according to another embodiment of the present disclosure.

FIG. 30 shows a semiconductor package including a 2.5D IC structure, according to another embodiment of the present disclosure.

FIG. 31 shows a semiconductor package including a 2.5D IC structure, according to another embodiment of the present disclosure.

FIG. 32 shows a semiconductor package including a 2.5D IC structure, according to another embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

This invention discloses methodologies, processes and structures to create 3D IC and 2.5D IC interconnect structures containing a FSPDN or a BSPDN that enable skip-die or multi-sided electrical interconnection, e.g., from the bottom die of 3D IC or the interposer directly to any other die in the 3D IC using a combination of RDLs, through vias (e.g., TSVs, TMVs, through-diamond vias, TDVs, and/or through-silicon-diamond vias, TSDVs), HTC supporters and HTC structural members (e.g., HTC interposer-style spacers such as diamond interposer-style spacers). These 3D IC and 2.5D IC structures also enable dual-sided or multi-sided system-level cooling from the top side of the 3D IC, its bottom side and chip sides in the 3D stack with the use of (but not limited to) a combination of RDLs, through vias, HTC supporters, HTC structural members (including HTC interposer-style spacers such as diamond interposer-style spacers), thermal isolation layers (including air gaps and thermal metamaterial structures), heat spreading layers, a heat spreader (or a lid), and a heatsink. The heat spread can include the heatsink, a HTC (e.g., copper or diamond) heat spreader a vapor chamber, or a HTC heat spreader or a vapor chamber integrated with the back cover of, for instance, a mobile device opposite to the display side (note: for liquid cooling applications, the heat spreader can be a cold plate and the heatsink a manifold). Materials having a thermal conductivity greater than that of the semiconductor material used for die construction in the same semiconductor package are called high-thermal-conductivity (HTC) materials herein. Although diamond is used here for demonstration, other HTC materials can also be considered. Diamond possesses the highest thermal conductivity (TC at ˜2000 W/m·K and beyond) of any known material on earth at temperatures above ˜100 K, which is greater than 5 times that of copper, extremely high breakdown field (˜20 MV/cm), and extremely low thermal expansion coefficient (˜1 ppm/° C. at room temperature). As in the case of silicon interposers, diamond can be used to create diamond interposers containing RDLs and TDVs using the processes disclosed herein. Diamond is therefore chosen here for illustration as it is the premium material for heat spreading for micro-electronics.

In some embodiments, the HTC material described herein may include other materials besides diamond, for instance, graphene, boron nitride, boron arsenide, cubic boron arsenide, aluminum nitride, silicon carbide, or a combination thereof, and the HTC substrate used in forming the composite wafers can be composed of silicon, diamond, graphene, boron nitride, boron arsenide, cubic boron arsenide, aluminum nitride, silicon carbide, or a combination thereof.

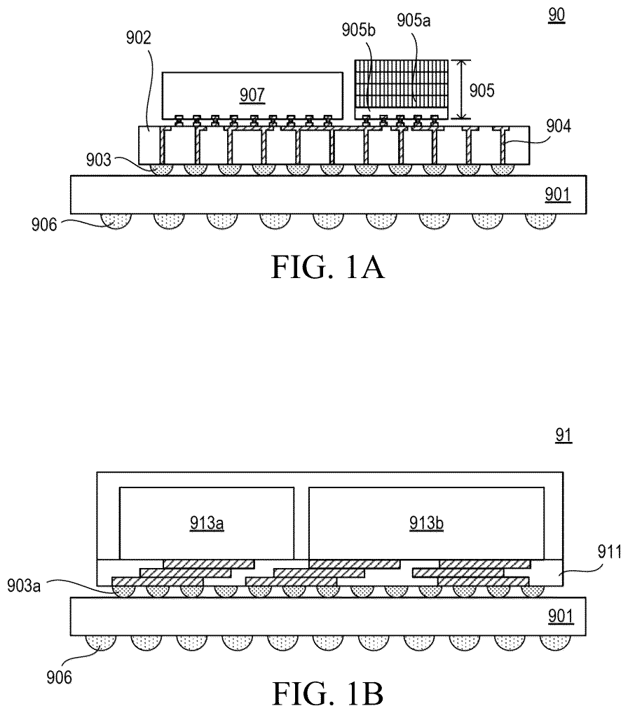

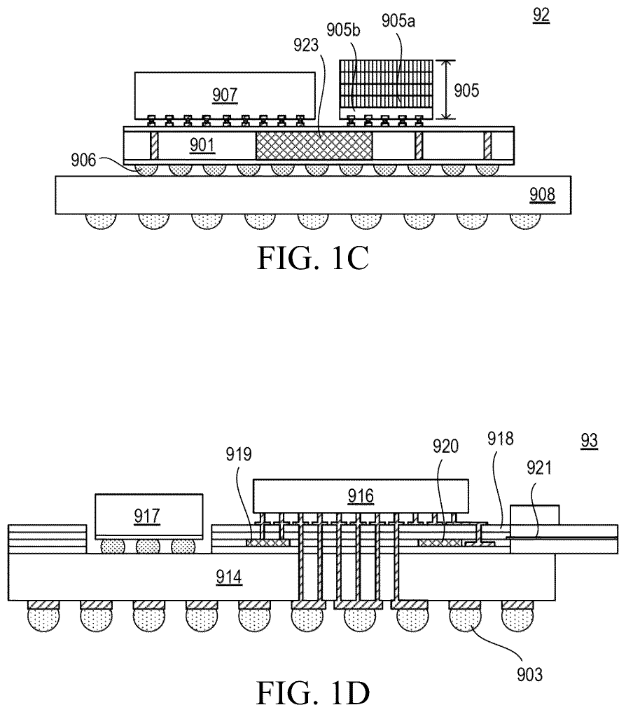

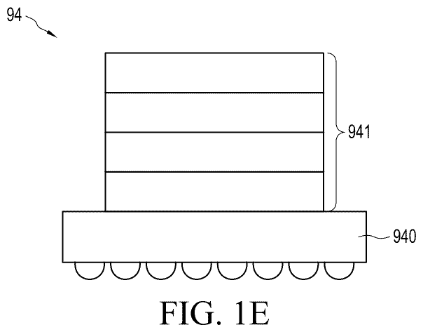

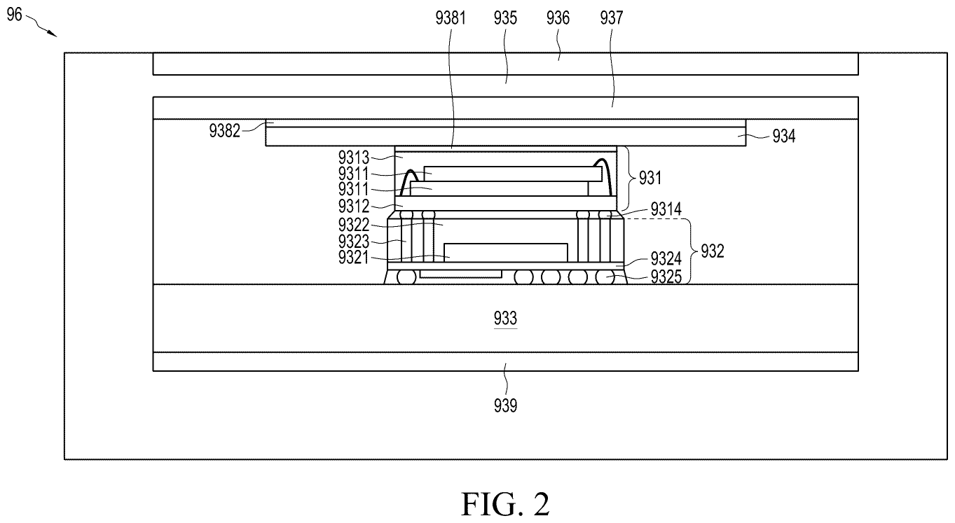

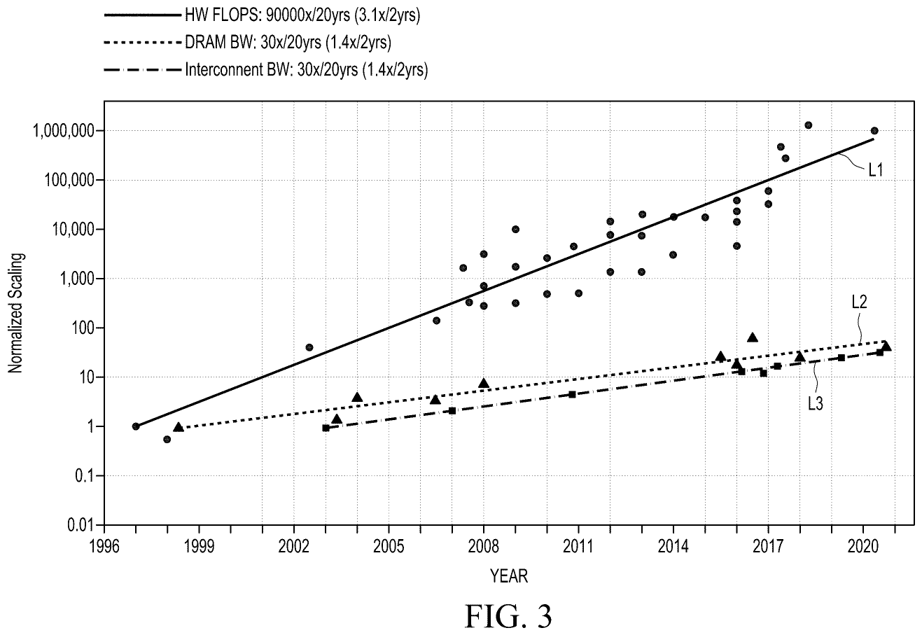

The 3D ICs disclosed herein can contain ICs of the same, similar or different sizes. The IC in the 3D IC structures can contain an active IC in bare die form, an IC embedded in a laminate substrate or molding compound, a multiplicity of ICs in the same package layer, an interconnect structure such as an interposer (e.g., the HTC supporters) or an interposer-style spacer (a HTC structural member), a discrete/passive or an embedded passive element, a micro-electromechanical (MEMS) device, and other types of electronic components embedded. The ICs, interposers and spacers can contain through vias, and RDLs on both the front-side (the wafer back-end-of-the-line, BEOL) side of the IC and its bottom side. Embedding the ICs, diamond interposers and/or diamond plates using a molding compound also allows one to create TMVs within the molding compound, connecting the RDLs on the top and bottom sides of the embedded IC structure in a stacking layer. Each stacking layer containing an IC or more can be of the same sizes or of different sizes compared to other stacking layers in the 3D IC structures. Even though 3D IC and 2.5D IC structures are used for demonstration, the methodologies, processes and structures can also be applied to other enabling advanced system-in-a-packages (SiPs) comprising fan-out, embedded SiP, silicon photonics and their combinations including those illustrated in FIGS. 1A to 1E particularly when the SiPs are used to incorporate a multiplicity of die in the package-thickness direction (z-direction).

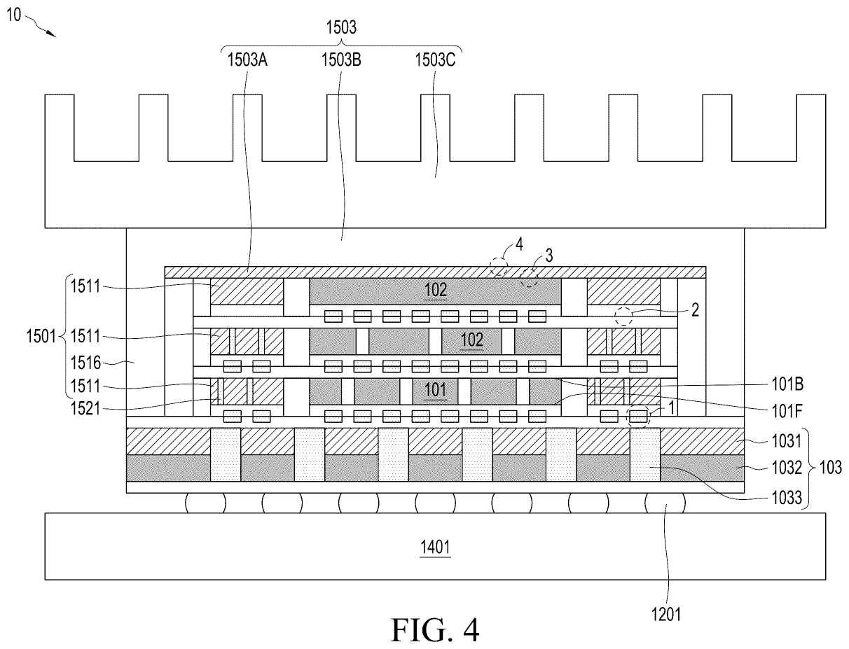

Using 3D IC as an example, FIG. 4 shows a semiconductor package 10 according to one embodiment of the present disclosure. The semiconductor package 10 includes dies, 101 and 102, each of which containing a FSPDN, a HTC supporter 103, a HTC structural member 1501, a HTC heat spreader and heatsink 1503. In some embodiments, the die 101 may be a processor die or a logic die, and the dies 102 can be memory dies, such as DRAM dies or static random access memory (SRAM) dies including control dies as warranted. As shown in FIG. 4, the dies, 101 and 102, can be of the same sizes for demonstration purposes here (or can be of different sizes) and can be embedded in a molding compound over the supporter 103. Specifically, the memory dies and control dies 102 can be stacked over the processor die 101.

The HTC supporter 103 is disposed immediately under the die 101 and thermally coupled to the die 101. Furthermore, the thermal conductivity of the supporter 103 is greater than a thermal conductivity of the die 101; therefore, the heat generated by the die 101 can be dissipated in a downward direction through the HTC supporter 103 which out-perform a low-thermal-conductivity (LTC) supporter such as a laminate substrate or a PCB.

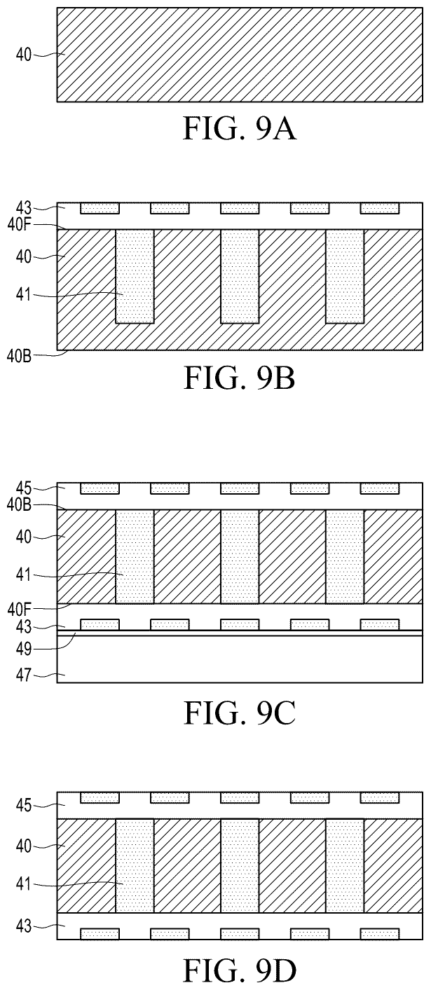

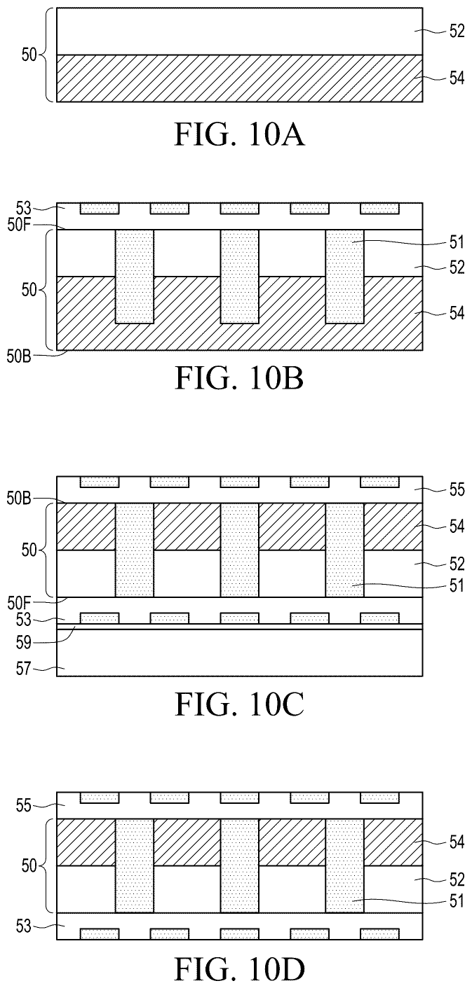

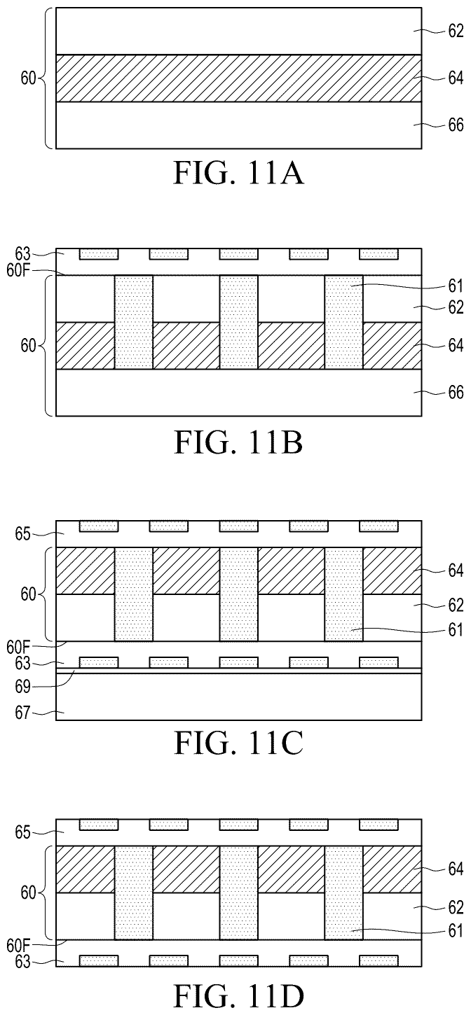

The supporter 103 includes a HTC interposer composed of a material with a thermal conductivity greater than that of the die 101, which, for example, can be composed of silicon or other suitable HTC materials that are amenable to microfabrication. In some embodiments, the supporter 103 can be composed of HTC materials including diamond, silicon, graphene, boron nitride, boron arsenide, cubic boron arsenide, aluminum nitride, silicon carbide or a combination thereof. The supporter 103, for example, can be a diamond interposer containing RDLs on its top and bottom sides and TDVs, which can be built using a full-sized (12″ in diameter), reconstituted diamond wafer and the process described in FIGS. 9A to 9D. Furthermore, the supporter 103 can be built using a full-sized (e.g., 12″ in diameter), reconstituted silicon-diamond composite wafer (e.g., a bi-wafer or a tri-wafer) and the process shown in FIGS. 10A to 10D or FIGS. 11A to 11D. It includes a diamond portion 1301 and a silicon portion 1032 with through-silicon-diamond vias (TSDVs) 1033 formed therein. The TSDVs 1033 may be adopted as power vias, signal vias, optical vias and/or thermal vias according to application. The supporter 103 can further be mounted on an organic laminate substrate 1401 or a PCB through solder bumps 1201 as shown in FIG. 4.

In addition, the HTC supporter 103 may have a cross sectional width greater than the sectional width of the die 101, so that the HTC structural member 1501 can be disposed side-by-side with the dies 101 and 102 on the supporter 103 and be thermally coupled to the supporter 103 (see FIG. 4). The structural member 1501 includes interposer-style spacers 1511 composed of a HTC material with a thermal conductivity preferably greater than that of silicon. For example, the spacers 1511 can be HTC interposers such as diamond interposers that are placed side-by-side with the dies 101 and 102 at each stacking layer. These HTC spacers 1511 enable the heat generated by the dies, 101 and 102, in each stacking layer, to be dissipated in a lateral direction in each stacking layer and the supporter 103 so as to further be dissipated both in an upward direction to the heat spreader 1503 and in a downward direction to the supporter 103. In some embodiments, the spacers 1511 referred herein can also be silicon interposers or interposers. In some embodiments, the spacers 1511 (and also other elements of the structural member 1501) can be composed of HTC materials including diamond, silicon, graphene, boron nitride, boron arsenide, cubic boron arsenide, aluminum nitride, silicon carbide or a combination thereof. The HTC spacers 1511 can be a diamond interposer containing RDLs on its top and bottom sides and TDVs or a silicon-diamond interposer containing RDLs on its top and bottom sides and TSDVs as in the case of HTC supporter 103.

The semiconductor package 10 also enables skip-die or multi-sided power and signal distributions in addition to the traditional 3D IC's one-die-at-a-time distributions, e.g., from the substrate to the processor, then from the processor to the control IC and then from the control IC to the bottom DRAM die, one-die-at-a-time, etc. For example, the skip-die design allows the power and signal to be transmitted from the die 101 to the die 102 at the top by taking advantage of appropriate routing involving the spacers 1511, through vias (e.g., TSVs in the dies, TDVs or TSDVs 1521 in the spacers 1511 and/or TMVs—not shown), RDLs and flip chip or copper hybrid bonds while bypassing the die 102 at the bottom.

Also, the semiconductor package 10 enables dual-sided or multi-sided cooling of the 3D IC structure with the heat dissipation paths of logic die 101, which can be a high-power processor, (1) from the top side (e.g., the top memory die 102) of the 3D IC structure to the heat spreader 1503, and (2) from the bottom side of 3D IC structure, i.e., from the logic die 101 downwards to the HTC supporter 103 (e.g., silicon-diamond interposer) and then upwards to spacers 1511 and structural member 1501 placed side-by-side with the ICs to the heat spreader 1503.

The heat spreader 1503 is disposed over the dies 101, 102, and the structural member 1501. The heat spreader 1503 can include a HTC thermal interface material (TIM) or a HTC layer 1503A (e.g., made of diamond), a HTC lid (e.g., made of copper), a vapor chamber or a HTC integrated heat spreader 1503B, and a HTC heatsink 1503C (e.g., a fin-type or a planar heatsink). In some embodiments, the HTC structural member 1501 may further include vertical leads 1516 thermally coupled to the heat spreader 1503 and the supporter 103. The vertical leads 1516 may be made of a HTC material, for example, the same material as the lid 1503B, so the heat transmitted to the HTC supporter 103 can be dissipated upward towards the lid 1503B through not only the spacers 1511 but also the vertical lead 1516, thereby further improving the cooling efficiencies. In addition, in some embodiments, the lid 1503B may be thermally coupled to and integrated with the HTC layer 1503A with the use of a TIM or suitable bonding layers as needed, and the heatsink 1503C may also be thermally coupled to and integrated with the lid 1503B and the HTC layer 1503A with the use of a TIM or suitable bonding layers as needed. However, the present disclosure is not limited thereto.

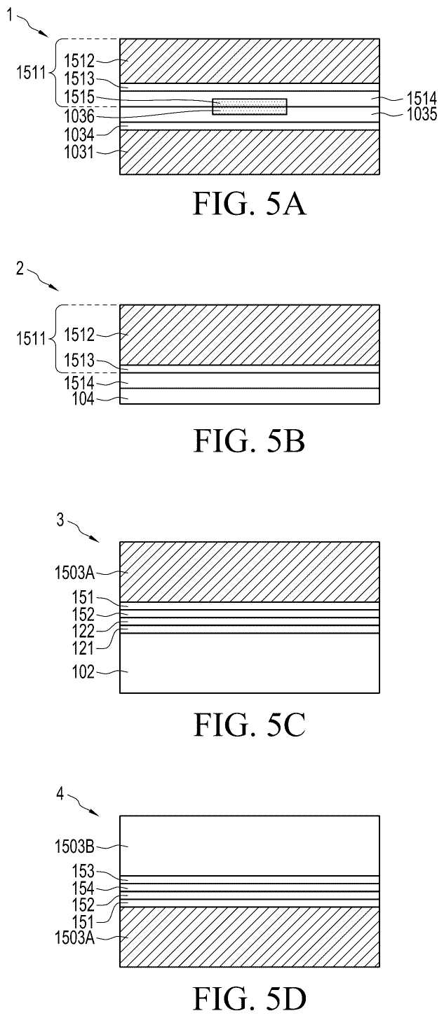

In some embodiments, the heat spreader 1503 can be an integrated heat spreader that is a metal exterior lid of a processor package. It serves as both a protective shell around the processor and a pathway for heat to be exchanged between the processor and the heatsink. In such case, the integrated heat spreader can be attached to the backside of the processor with a TIM such as a thermal paste. The integrated heat spreader is a combination of a typically rectangular heat spreader ring bonded to the substrate (e.g., the supporter 103 or a laminate substrate) supporting and surrounding the processor to protect the processor and a planar heat spreader placed on top of the rectangular heat spreader ring. The HTC layer 1503A or the integrated heat spreader 1503 can be optionally disposed (e.g., using direct bonding or bonding involving bonding layers—see FIGS. 5A to 5D) on the top dies 102 and on the top spacers 1511 to enable direct thermal and/or physical contact with the top dies 102 and top spacers 1511. In some other embodiments, the components of the heat spreader 1503 may further include a metal lid, vapor chamber, a cold plate, a manifold or a combination thereof.

In the present embodiment, the HTC layer 1503A (e.g., a HTC diamond plate) which is disposed between the lid 1503B and the top dies 102 and the top spacers 1511 in the 3D IC structure can cover the interior of the lid 1503B which can be many times larger in area compared to the 3D IC structure beneath for enhanced heat spreading.

With regard to the heat spreader 1503, a copper heatsink provides better thermal performance compared to an aluminum heatsink. A copper vapor chamber is a two-phase device and a planar heat pipe comprising an evaporator (which makes contact with the hot chip), a vacuum sealed vapor chamber containing a working fluid such as water which transfers heat from the evaporator to the condenser and a condenser where the vapor condenses and gives off the heat and the liquid flows back to the evaporator. The low pressures inside the chambers allows water to vaporize at a temperature much lower than normal boiling temperature (i.e., 100° C.), thereby creating an isothermal heat spreader. A vapor chamber, which can be formed to the size of the electronics to be cooled, spreads the heat in two dimensions and is typically 1 to 5 mm thick. It can be used instead of solid copper to form the heat spreader 1503 for up to 90 times thermal performance improvement. The effective thermal conductivity of vapor chambers is estimated to be between 5000 and 20,000 W/m·K which is far better than the most thermally conductive material, i.e., diamond on earth. Vapor chambers can draw heat from the heat source to a heatsink placed at a remote location (>150 mm away) where there is space for the heatsink and cooling medium (e.g., air or liquid). Bonding the vapor chamber to the base of a heatsink or the back cover of a mobile device is particularly useful where there is a small concentrated heat source versus a large heatsink base. Vapor chambers are particularly useful for cooling applications where power density is high, say, between 20 W/cm² and 500 W/cm². In these applications, it is often critical that heat is quickly spread to a larger surface area.

FIGS. 5A to 5D show the detailed structures of interfaces 1 to 4 in the semiconductor package 10 in FIG. 4 with the spacers 1511 and the supporter 103 built using diamond as the substrate material for illustration. The processes to form diamond interposers with RDLs on both their top and bottom sides and TDVs can be seen in FIGS. 9A to 9D, while the processes to form silicon-diamond interposers with RDLs on both their top and bottom sides and TSDVs can be seen in FIGS. 10A to 10D, and FIGS. 11A to 11D. In FIG. 5A, the interface 1 between the supporter 103 and the spacer 1511 is shown, which is created by copper hybrid bonding between the bonding layer 1514 on the diamond portion 1512 of the spacer 1511 and the bonding layer 1035 on the diamond portion 1031 of the silicon-diamond supporter 103. Surface layers, 1513 and 1034, are optional layers including titanium (Ti), silicon (Si) or tungsten (W) layers which form chemical bonds with diamond and which can be deposited by physical vapor deposition (PVD) such as sputtering on the spacers 1511 and the supporter 103. In some embodiments, the respective surface bonding layers, 1035 and 1514, on the supporter 103 and the spacer 1511 can be part of the redistribution layers (RDL) on the supporter 103 and the spacers 1511, and the supporter 103 and the spacers 1511 can be bonded via the bonding pads 1036 on the RDL of the supporter 103 and the bond pads 1515 on the RDL of the spacers 1511 by using copper hybrid bonding or flip chip bonding based on micro-bumps with the use of a non-conductive paste or film (NCP). Furthermore, the spacers 1511 may include TDVs 1521 and the supporter 103 may include TSDVs 1033 as shown in FIG. 4, such that signals, power and heat can be transmitted in a skip-die, dual-sided or multi-sided manner. Bonding of die, for example, die 101, to the supporter 103 involves processes and structures similar to those to form interface 1 (FIG. 5A). These processes and structures can also apply to die-to-die (e.g., die 102 to die 101 and die 102 to another die 102) bonding to form the 3D structure in FIG. 4. In some embodiments, bonding of spacers 1511 to ICs can also be done with, for example, die 102 replaced by the spacers in FIG. 4 using the structures and related processes described in forming interface 1 in FIG. 5A.

Copper hybrid bonding can be achieved based on, for example, silicon dioxide (SiO₂)-to-SiO₂ bonding or polyimide (PI)-to-PI bonding. Direct oxide-to-oxide bonding can proceed in the following process sequence: (1) planarization of the bonding surfaces to a arithmetic or root-mean-square roughness <1 (or 0.5) nm per application; (2) formation of dangling bonds through plasma activation using gases such as N₂ (nitrogen)/O₂ (oxygen)/Ar (argon); (3) removal of defects and surface wetting through deionized water cleaning; (4) bonding of wafers (e.g., the spacers 1511 and the supporter 103) containing oxide bonding layers at room temperature and atmospheric pressure via the formation of hydrogen bonds between two to three monolayers of water molecules and polar hydroxyl (OH) groups (which terminate at both the native and thermal SiO₂); (5) formation of van der Waals bonds between H₂O molecules and silanol groups (Si—OH—(H₂O)x-HO—Si; silanol group ═Si—OH) on the top and bottom bonding surfaces; and (6) annealing to remove water molecules at the interface and form permanent covalent bonds at temperatures typically less than 400° C., preferably below 250° C. During the planarization step (1), it is also important to control the recesses of the bonding pads, typically, copper bonding pads, to ensure high copper hybrid bonding yields. Regarding oxide-to-oxide bonding, one can vary oxide type and deposition technique, process conditions such as plasma gas, plasma power, surface roughness pertaining to chemical mechanical polish (CMP), surface cleanliness, mono to multiple layers of water molecules from de-ionized cleaning, bonding conditions (such as temperature, speed and pressure), and anneal conditions (e.g., anneal temperatures, anneal time and number of annealing steps) to maximize the bonding or shear strength between the two components being bonded (e.g., the spacers 1511 and the supporter 103). Void formation caused by water droplet formation (the Joule-Thomason expansion effect) at wafer edge during direct bonding must be avoided by controlling key parameters including plasma conditions, surface roughness, degree of cleanliness, wafer warpage/flatness, bonding conditions, etc.

Besides oxide-to-oxide bonding, polyimide-to-polyimide bonding based on, for instance, a fully cured polyimide based on pyromellitic dianhydride (PMDA) and 4,4′-diaminodiphenyl ether (4,4′-ODA) to form the bonding layers can also be considered to achieve copper hybrid bonding with the application of an external pressure as needed. In this case, one can tailor the shear strength by varying conditions such as volume of water introduced, bonding time, and oxygen (02) plasma activation time to maximize the shear strength between the supporter 103 and the spacers 1511. To achieve void-free PI-to-PI bonding, it is important to activate the PI surfaces by oxygen plasma activation to generate low-density hydrophilic groups on the PI surface which effectively enhances adsorption of water molecules introduced by a de-ionized water wetting process. The adsorbed water molecules, in turn, brings in considerable high-density OH (hydroxyl) groups which facilitate pre-bonding. Following PI surface activation and wetting, PI-to-PI hybrid bonding can take place at a relative low temperature of 250° C. for a few minutes only when a permanent bond is desired. Neither the plasma process nor the wetting or hydration process alone can achieve good bonding. Key parameters to manipulate in order to achieve a good bond include plasma activation time, volume of water introduced, bonding temperature and bonding time.

In FIG. 5B, the interface 2 between the two diamond spacers 1511 is shown, and the spacers 1511 can be bonded through bonding layers 104 formed on the two spacers 1511 (only the top one is shown in FIG. 5B as the bottom one is of a similar construction). Optionally, surface layers (of Ti, Si or W) 1513 can be deposited prior to formation of the bonding layers.

As in the case of FIG. 5A, the layers disposed on the spacers 1511 can contain a bonding or RDL layer 1514 with a surface bonding layer 104 on top of it. The top spacers 1511 though not shown can also contain TDVs serving as thermal vias to enhance upward heat dissipation.

In FIG. 5C, the interface 3 between the top die 102 and the HTC layer 1503A (see also FIG. 4) is shown based on diamond for illustration although this HTC layer can also be a HTC TIM or made of other HTC materials as indicated above. Bonding between diamond and the backside of the die, e.g., silicon, can be achieved through direct bonding without involving the surface bonding layers shown in FIG. 5C. This can require planarization of the bonding surfaces of the diamond layer 1503A, top spacers 1511 and silicon of the top dies by CMP and deep reactive ion etching (DRIE) as needed with or without the use of a sacrificial layer such as silicon dioxide to a surface roughness of, for example, less than 1 nm, and also pre-conditioning of all surfaces as needed. Pre-bonding conditioning of diamond and silicon surfaces can involve (1) wet surface pre-treatments involving ultrasonic de-ionized (DI) water clean, H₂SO₄/H₂O₂ treatment, NH₃/H₂O₂ treatment, and N₂ blow dry, (2) plasma/inductively coupled plasma reactive ion etching (ICP-RIE): O₂, H₂/O₂, (3) deep RIE (DRIE): O₂/CF₄, SF₆/O₂, and/or (4) activation of the bonding surfaces inside bonding machines prior to bonding by a fast atom beam gun, FAB (using, for instance, argon neutral atom beam at ˜1 keV), or by an ion gun (using for instance, argon ion at ˜60 eV) to remove oxide films in vacuum and to reveal dangling bonds at the surfaces for bonding. It should be noted that (1) FAB works well for (sputtered) Si/Si, Si/SiO₂, metals, compound semiconductors and single crystal oxides, while ion guns is known to work for SiO₂/SiO₂, Glass, Si₃N₄ (silicon nitride)/Si₃N₄, Si/Si, Si/SiO₂, metals, compound semiconductor, and single crystal oxides, some of which can be deposited as bonding layers to facilitate bonding yields as needed, and (2) a vacuum of 10⁻⁶ Pa (pascal) is preferred during bonding to prevent re-adsorption to activated bonding surfaces.

When direct bonding between diamond and silicon and between diamond and diamond present a challenge following pre-bonding surface conditioning, a glue or bonding layer can be used. As shown in FIG. 5C, the surface layer 151 (e.g., Ti, Si or W layer) and the bonding layer 152 (e.g., Au or a solder) can be deposited on the HTC layer 1503A. The backside of the top die 102 (e.g., silicon) can be deposited with a good diffusion barrier layer 121 including Ti, TiN, Ti/TiN or Ti/Ni and a bonding layer 122 such as Au or a solder when metals are used to form the bonding layers to enable low-temperature bonding at temperatures preferably below 250° C. The top die 102 and the HTC layer 1503A can be bonded with the respective bonding layers, 152 and 122. In some other embodiments, the bonding layers, 152 and 122, can be ultrathin non-metal glue layers such as CVD poly-silicon (poly-Si) layers that can be deposited on diamond or on both diamond and silicon as intermediate bonding layers to achieve high, low-temperature direct bonding yields between diamond and silicon. Poly-Si (whose TC is over 100 times that of SiO₂) is preferred over SiO₂ for use to create the thin bonding layers in terms of minimizing the thermal resistivity impact to the final 3D IC or package structure. Bonding layers are typically ultrathin, around 100s nm or less than 100 nm in thickness, to minimize their thermal impacts. Higher-TC and lower-coefficient-of-thermal-expansion (LCTE) bonding materials are preferred as the CTEs of both diamond and silicon are low (<3 ppm/° C.). Bonding layer candidates include the aforementioned Ti/Au, poly-Si, silicon dioxide and polyimides (the latter two are for direct bonding involving oxide-to-oxide bonding for example), as well as others below and their combinations: (1) non-metals: Si (e.g., poly-silicon), SiO₂, Si₃N₄, Al₂O3₃ (alumina), diamond, boron nitride, graphene, polyimides, (2) metals: Ti, W, Pt, Cr, Au, Cu, Ir, nickel (Ni), iron (Fe), Ag—In, Au—In, Ag, Sn, solders, transient liquid bonding metals, and (3) metal-on-oxides: Ir on SrTiO₃, Ir on YSZ/Si, Ir on MgO, sapphire or TaO₃.

Following deposition, bonding layers can be pre-conditioned as needed through a combination of the aforementioned planarization processes and pre-bonding surface pre-treatments, DRIE (e.g., using a mixture of SF₆ and O₂), plasma/ICP-RIE (using O₂, Ar, N₂, Ar/O₂), and FAB (using, e.g., Ar neutral atom) or ion gun (using, e.g., Ar ion) in bonding stations. Application of both a bonding pressure and encapsulation of bonding surface heterogeneities by the bonding layers can be considered as needed to increase the C2 W (chip-to-wafer; or wafer-to-wafer, W2 W) bonding yield. Bonding can also proceed by C2 W or W2 W bonding in vacuum and at a low temperature (preferably room temperature) under the application of a bonding force, followed by annealing at temperatures preferably less than 250° C. In the case of transparent diamond (e.g., single crystal diamond, SCD), a pico-second 355 nm pulsed laser can also be used to enhance the bonding quality and yield. C2 W bonding can be achieved with high-accuracy thermo-compression bonders (TCB) while commercially available W2 W bonders are available for W2 W bonding. Oxide-to-oxide based W2 W (or C2 W) bonding which is capable of delivering ultrahigh integration densities, relies on the use of a bonding layer (e.g., SiO₂) deposited on two opposing wafer surfaces to achieve self-aligned wafer-to-wafer bonding at relatively low temperatures, typically less than 400° C. and preferably less than 250° C. Many of the aforementioned bonding layer candidates including Si₃N₄ can also be considered here. Thermal exposure that does not exceed 400° C. allows the use of conventional metallization and low-x dielectrics such as Cu and carbon containing low-x BEOL when active ICs are involved in bonding. Two additional advantages of low-temperature bonding are avoidance of excessive wafer deformation due to thermal expansion match effects, and minimizing the thermal effects on the lower layer transistor high-x metal gate stacks and functions.

In FIG. 5D, the interface 4 between the HTC layer 1503A using diamond for illustration and the lid 1503B is shown. As shown in FIG. 5D, the surface layer 151 and the bonding layer 152, as previously described, can be formed on the HTC diamond layer 1503A, and a surface layer 153 and a bonding layer 154 as previously described can also be formed on the metal lid 1503B when a HTC material such as diamond is used to form at least part of the lid 1503. When a metal lid 1503A is involved, a TIM can be used to bond the HTC diamond layer 1503A and the metal lid 1503B.

More details will be provided below involving four interfaces, 1 to 4. The bonding layers which appear as the top layers of the RDLs (such bonding layer is part of RDL and on the surface of the RDL) at interfaces 1 and 2 (FIGS. 5A and 5B) can be either silicon dioxide or PI based and can be formed on the diamond surfaces pre-coated with typically Ti, Si, or W which reacts with diamond and forms stable carbides. Ohmic metal carbide contacts can be formed on diamond using thin film, multilayer metal coatings with the carbide former as the basis for adhesion, followed by the deposition of optionally an intermediate bonding layer such as nickel (Ni) or nickel-vanadium (Ni—V) and a stable inert metal such as a noble silver (Ag) or gold (Au) layer as the final bonding layer (for interfaces 3 and 4). These coatings on diamond are stable up to ˜400° C. and can be used for attachment of, for instance, the diamond layer 1503A to the backside of the IC (e.g., top memory die 102) at the interface 3 (FIG. 5C) pre-coated with a barrier layer and to the lid 1503B at the interface 4 (FIG. 5D).

To prevent metal diffusion in the IC silicon (Si) substrate at interface 3 (FIG. 5C), a diffusion barrier layer 121 is needed on the Si backside. This barrier layer 121 can be Ti, chromium (Cr) or tungsten (W). A stack of Ti, Ti/nickel-vanadium (Ni—V) and Ag can be sputter deposited on Si backside following in-situ sputter etching using argon (Ar) to remove native oxides from the Si backside to prepare the Si for bonding where (1) the Ti layer can serve as the barrier to Ni diffusion towards Si, (2) the Ni—V layer, a solderable intermediate layer, forms good bonds with soft solders, and (3) the bonding Ag layer protects the underlying layers from oxidation and enables solderability.

The Ti/Ni-V/Ag metal stack can be tailored to achieve low stresses and low wafer warpage which is particularly important for thin ICs commonly found in 3D IC structures by adjusting sputtering conditions. Ag-to-Ag and Au-to-Au bonding using a TCB can take place at temperatures below 250° C. Ag and Au have high thermal conductivities at 430 W/m·K, and 320 W/m·K, respectively (versus ˜400 W/m·K for copper and 148 W/m·K for silicon) and high melting points at 961° C. and 1064° C., respectively. Au is costs higher compared to Ag. Ag and Au can be sputter deposited or plated. Interface 3 can be formed by, for instance, bonding Ti/Ni-V/Ag on Si to Ti/Ag on diamond, bonding Ti/Ni-V/Au on Si to Ti/Au on diamond or bonding Ti/Au on Si to Ti/Au on diamond while Ti/Au on diamond can also be Ti/platinum (Pt)/Au on diamond. The lid 1503B and the heatsink 1503C can be made of copper, silicon, diamond or other higher-TC materials mentioned above.

Bonding of high TC layer 1503A to the lid 1503B at interface 4 (FIG. 5D) can be achieved by, for example, bonding of Ti/Au or Ti/Ag on both diamond and the lid or in a fashion similar to that to behind the formation of interface 3 with the exception that no barrier layer is needed here. In the present embodiment, the lid 1503B is supported by the vertical leads 1516 on the supporter 103, and bonding of the vertical leads 1516 to the supporter 103 can be based on a thermal interface material (TIM) or other HTC bonding materials (including solders with proper surface finishes at the bonding interface) placed on top of thermal vias in the supporter 103. In some embodiments, the heat spreader 1503 may be an integrated heat spreader, and can be bonded to the supporter 103 with similar approaches.

For bonding involving larger areas and unevenness or warpage as possibly in the formation of interface 4, Au and Ag can be co-deposited and used for bonding with or without an etching process of Ag afterwards. One can also consider use of sintered Ag high thermal semi-sintering materials or high thermal die attach materials such as those used in the making of optical transceivers for optical communications. Besides these, transient liquid phase bonding based on copper-tin (Cu—Sn), Ni—Sn, Au—Sn, Ag—Sn, silver-indium (Ag—In) or Au—In with bonding temperatures below 300° C. can also be considered with the use of vacuum vapor-phase soldering as needed to minimize void formation at the bonding interface.

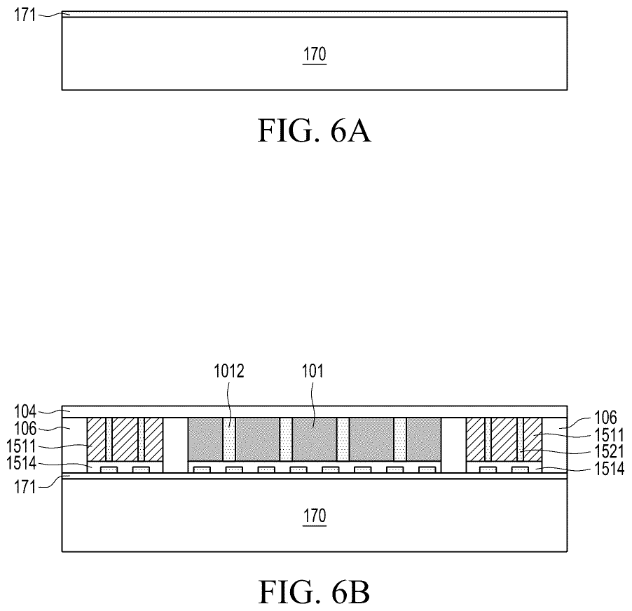

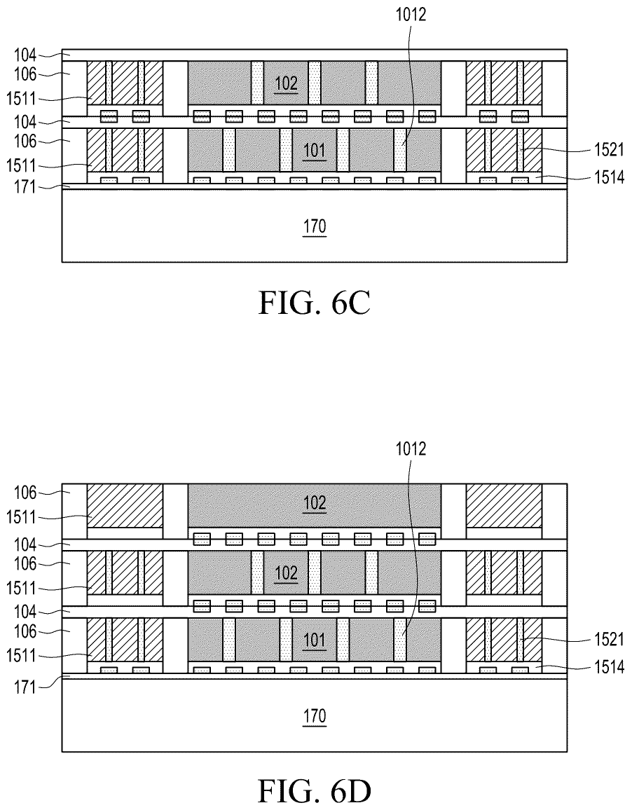

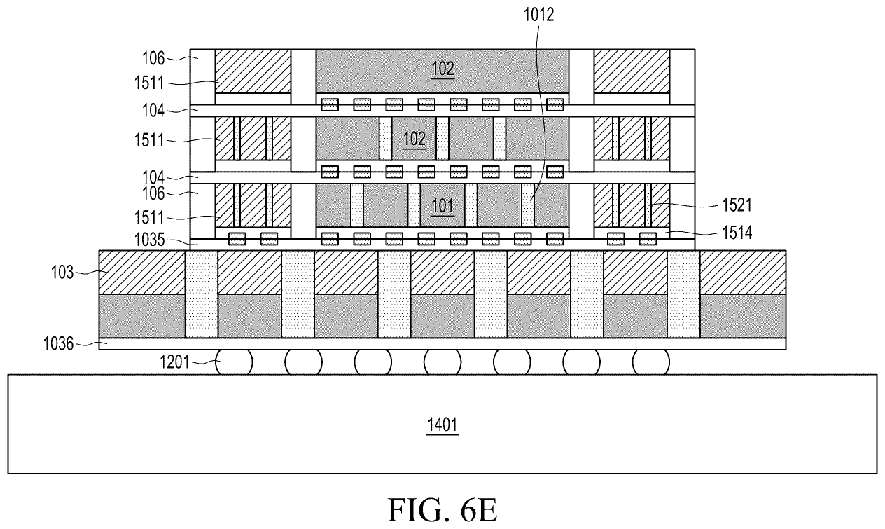

FIGS. 6A to 6E shows manufacturing operations to build the semiconductor package 10 in FIG. 4. In FIG. 6A, a release layer 171 is applied on a 12″ carrier 170, and the die 101 and the spacers 1511, each of which containing RDLs and through vias as needed, are bonded to the release layer 171. Bonding of die 101 and the spacers 1511 may require another temporary carrier containing another release layer (not shown here) depending on their thicknesses. In the present embodiment, the spacers 1511 are disposed side-by-side with the die 101 on the carrier 170. The die 101 and the spacers 1511 are subsequently overmolded with a molding compound 106, and the molding compound 106 is planarized to expose the TSVs 1012 in (or the RDL on) the die 101 and the TDVs 1521 in (or the RDL on) the spacers 1511. Next, another RDL 104 is formed thereon as shown in FIG. 6B.

FIG. 6C and FIG. 6D repeat the procedures described in FIG. 6B by stacking the second and the third layers of the dies 102 and the spacers 1511. Details can be referred to the description of FIG. 6B and are not repeated here for brevity.

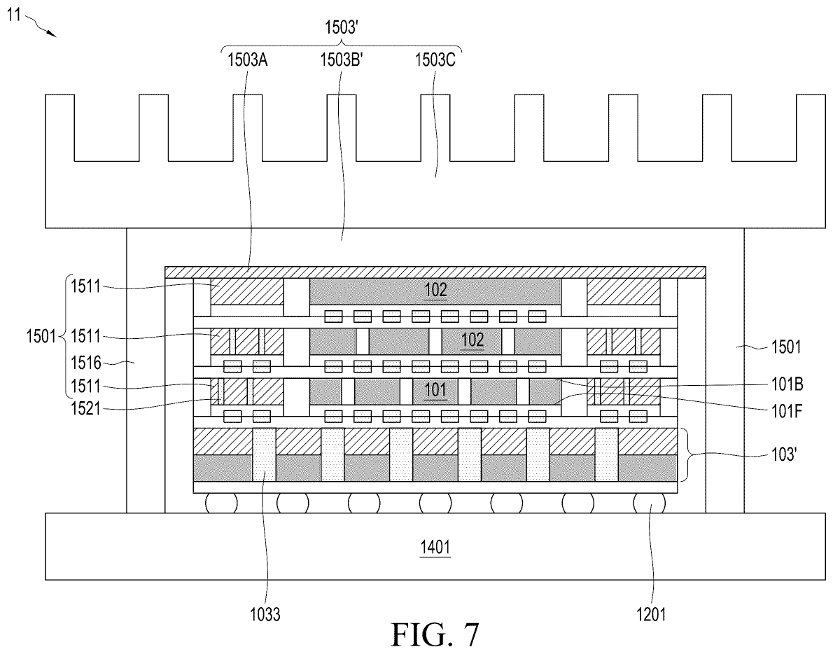

Following mounting of the 3D die structure in FIG. 6D on a wafer-mount tape supported by a wafer-mount frame, the carrier 170 (e.g., the 12″ glass) is released using a proper laser source, and the 3D IC stacking structure is diced and singulated, and the singulated 3D IC structure is bonded to the supporter 103 which can be in wafer form supported by a temporary carrier using a release layer with the carrier released following bonding and wafer mounting, singulated following release of the carrier, and bonded to the laminate substrate or PCB 1401. Alternatively, the individual 3D IC structure can be bonded to the supporter 103 pre-bonded to the laminate substrate or PCB 1401. Finally, the heat spreader 1503 including the HTC layer 1503A, the metal lid 1503B, and the heatsink 1503C can disposed on the 3D IC stacking structure with the lid 1503B thermally coupled to the supporter 103 through the vertical leads 1516. As a result, the semiconductor package 11 is formed as shown in FIG. 7.

FIG. 7 shows a semiconductor package 11 including a 3D IC structure according to another embodiment of the present disclosure. The difference between the semiconductor package 11 and the semiconductor package 10 (FIG. 4) is in that the semiconductor package 11 involves attaching the lid 1503B′ with the vertical leads 1516 to the laminate substrate 1401 instead of the supporter 103′. The semiconductor package 11 further involves stacking the two memory ICs for illustration (i.e., dies 102 covering control ICs; more than 2 dies 102 can also be stacked) on the logic IC (i.e., the die 101) first, and bonding the stack of dies 101 and 102 containing diamond spacers to a supporter 103′ (e.g., a silicon-diamond or a diamond interposer) which can be pre-bonded on the laminate substrate 1401 or which can be subsequently be bonded to the laminate substrate 1401.

The interfaces of die-to-die, interposer-to-die, interposer-to-spacer, spacer-to-spacer, HTC layer-to-top die and HTC layer-to-top spacer in the semiconductor package 11 are similar to those interfaces shown in FIGS. 5A to 5D, and thus are not further described for brevity.

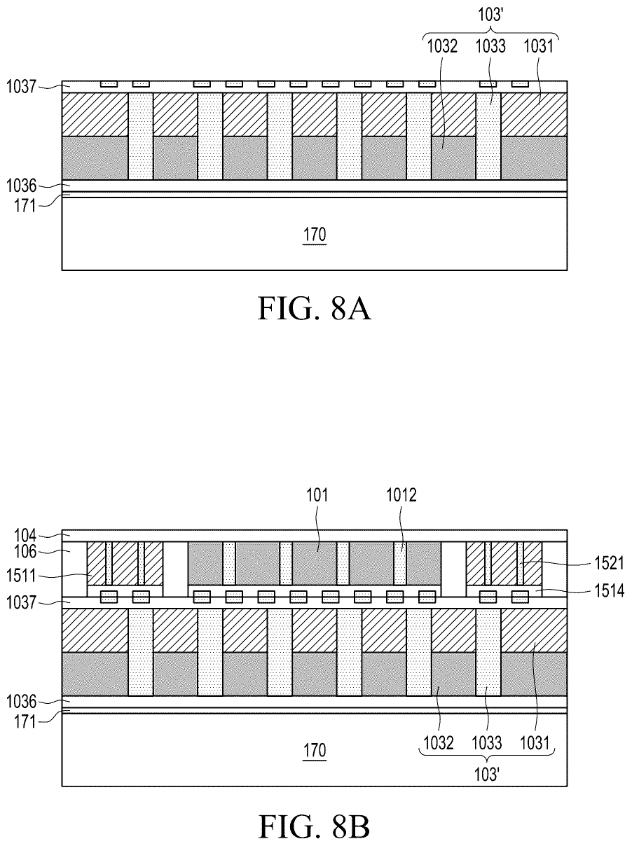

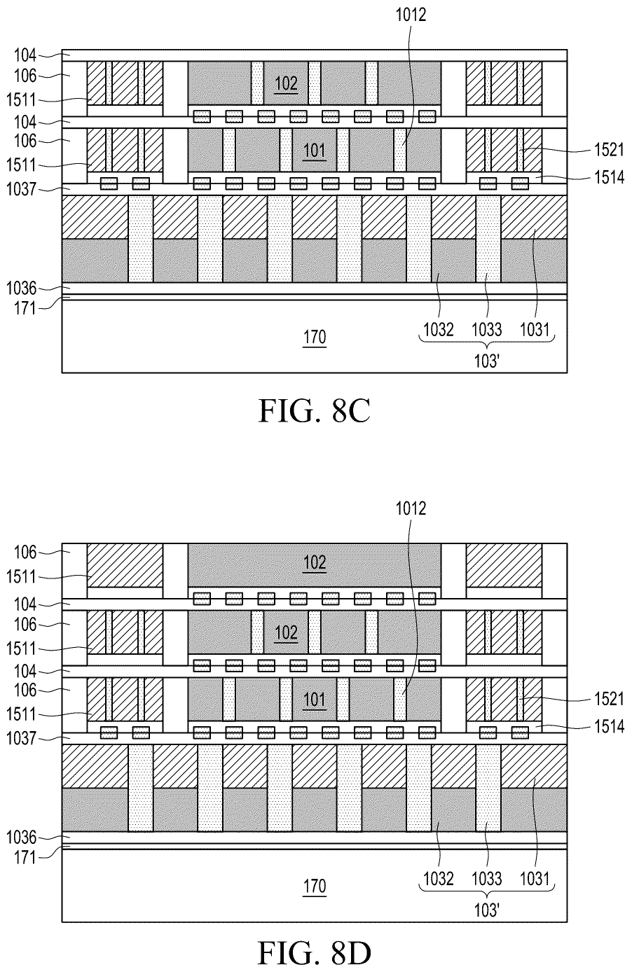

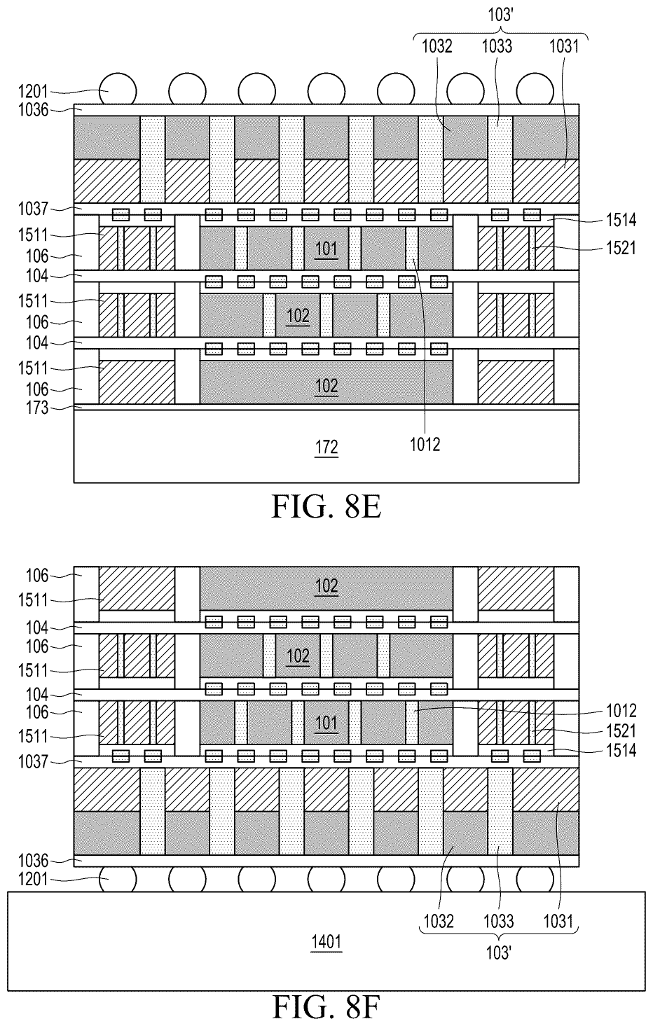

FIGS. 8A to 8F shows manufacturing operations to build the semiconductor package 11 in FIG. 7. In FIG. 8A, the supporter 103′ including the silicon portion 1032, the diamond portion 1031, and the TSDVs 1033, is provided using a silicon-diamond interposer containing RDLs on both its top and bottom side and TSDVs as an example (although it also be a diamond interposer). The TSDVs 1033 pass through the silicon portion 1032 and the diamond portion 1031, and are connected to RDLs, 1036 and 1037, formed on the two opposite surfaces of the supporter 103′. A carrier 170 (e.g., a 12″ glass carrier used in fan-out processing) is bonded to the supporter 103′ so as to and provide mechanical support to the support 103′, which is often thin, for example, 100 μm or smaller in thickness, with the use of a release layer 171 which can be released by a laser (or other means such as thermos-mechanical shearing and cleaning as needed).

In FIG. 8B, the die 101 and spacers 1511 that forms a part of the structural member 1501 are bonded to the supporter 103′ by hybrid bonding or flip chip bonding based on micro-bumps with the use of a NCP through RDL 1514 (with a surface bonding layer) of the spacers 1511 and RDL 1037 (with a surface bonding layer) of the supporter 103′. The die 101 and the spacers 1511 are overmolded by a molding compound 106, and the molding compound 106 is planarized using CMP and DRIE as needed with or without a sacrificial layer such as silicon dioxde to expose the TSVs 1012 in the die 101 (or the RDL or BEOL layers of the die 101) and the TDVs 1521 in the spacers 1511, followed by formation of a new RDL 104 thereon. FIG. 8C and FIG. 8D repeat the procedures described in FIG. 8B by stacking the second and the third layers of the dies 102 and the spacers 1511 to obtain the structure shown in FIG. 8D with the backside of the top die 102 and the top spacers exposed (without the molding compound). As mentioned previously, the top spacers 1511 placed side-by-side with the top die 102 can embody thermal vias (not shown). Details can be referred to the description of FIG. 8B and are not repeated here for brevity.

In FIG. 8E, another carrier 172 (e.g., a 12″ glass carrier) that provides mechanical support is attached to the backside (the side opposite to the side with FEOL and BEOL layers) of the top die 102 and the top spacers 1511 with the use of a release layer 173. The carrier 170 is then released using a proper means (such as laser irradiation), and solder bumps or micro-bumps with proper under-bump metallurgy (UBM) 1201 are formed on RDL 1036 of the supporter 103′ opposite to RDL 1037.

Following mounting of the structure in FIG. 8E on a wafer-mount tape supported by a wafer-mount frame, the carrier 172 is released using a proper laser source; the semiconductor package 11 is subsequently diced or singulated using a process including laser dicing, mechanical dicing, plasma/DRIE etch, wet etch or a combination thereof and the singulated structure as shown in FIG. 8E (without the carrier 172 and the release layer 173) is bonded to the laminate substrate or a PCB 1401 as shown in FIG. 8F. Finally, the heat spreader 1503′ including the HTC layer 1503A, the metal lid 1503B′, the heatsink 1503C, and TIMs as needed are disposed on the exposed top die 102 and the exposed top spacers 1511 of the structural member 1501 (shown in FIG. 8F) and the structural member 1501 on the laminate 1401, forming thermal coupling between the dies 102, the spacers 1511, the laminate 1401, the supporter 103′, the structural member 1501 and the heat spreader 1503. As a result, the semiconductor package 11 shown in FIG. 7 is formed.

Referring back to FIG. 7 (also to FIG. 4), The semiconductor package 11 (and also the semiconductor package 10) enables (1) skip-die or multi-sided signal and power distribution, i.e., power and signal can now be supplied directly from both the bottom die 101 and/or the interposer (i.e., the supporter 103′) supporting the bottom die 101 on the bottom-side to not just the die 101 directly above but also to all other dies 102 in the die stack in addition to the traditional one-sided interconnection from the bottom die 101 (to the die directly above and then from the die above to yet another die above, etc., one-die-at-a-time), and (2) dual-side or multi-sided cooling of the 3D IC structure (containing the logic die 101 which can be a high-performance, high-power processor) with the heat flows upward to the heat spreader, sideways to the HTC spacers and downward to the HTC supporter.

Using the structure in FIG. 7 as an example, the heat, specifically, can be dissipated from (1) the die 102 on the top side of 3D IC structure upward to the lid 1503B′ to the heatsink 1503C, and (2) the bottom side 101 of 3D IC structure, i.e., the logic die 101, downward to the HTC supporter 103′ (e.g., a silicon-diamond interposer) and then upward to HTC spacers 1511 and the structural member 1501 placed side-by-side with the ICs 101 and 102 to the diamond plate (i.e., the HTC layer 1503A) to the lid 1503B′ to the heatsink 1503C.

FIGS. 9A to 9D provide a process to create advanced diamond interposers (e.g., the spacers 1511 and the supporter 103/103′) or diamond based ICs from full-sized (e.g., 12″ in diameter), reconstituted diamond wafers. To create the diamond interposers from full-sized reconstituted diamond wafers, one can begin with a full-sized (e.g., 12″ in diameter), diamond substrate 40 (for instance, about 100 μm thick and approximate to a thickness of a 2.5D silicon interposer) as shown in FIG. 9A, and subject it to deep reactive ion etching (DRIE, or the so-called Bosch process) utilizing oxygen as the etch gas (in conjunction with other heavier gases such as CF₄) and a mask such as aluminum/silicon dioxide, aluminum/silicon/aluminum, or stainless steel to create high-aspect ratio through diamond via (TDV) hole (not shown) at high etch rates. In some embodiments, thousands of the TDV holes with 20 μm in diameter at an aspect ratio of 5 are created per wafer after DRIE operation. Other mask choices that can be considered include aluminum, titanium, gold, chromium, silicon dioxide, aluminum oxide, photoresist and/or spin-on-glass. The etch mask material needs to be etched slower than diamond in DRIE with high selectivity. Ultra-short-pulse (e.g., femtosecond-pulsed) laser micromachining can also be used with appropriate etch and clean operations or in conjunction with the DRIE processes for improved etch performance. A combination of DRIE and epitaxial deposition can create ultra-high-aspect-ratio (up to 500) holes in silicon. It may also be fashioned after to create ultra-high-aspect-ratio TDVs. Following TDV hole opening, one may implement (optionally) plasma enhanced chemical vapor deposition (PECVD) of oxide, and physical vapor deposition (PVD) of barrier/seed titanium/copper (Ti/Cu) or tantalum nitride/Cu (TaN/Cu) by sputtering and then copper (Cu) plating to fill the TDV holes. Subsequently, chemical mechanical polish (CMP) and DRIE as needed with or without the use of a sacrificial layer such as silicon dioxide can be utilized to remove the overburden Cu and complete the TDVs 41. RDL 43, for example, a micrometer-level fine-line RDL, and surface finish (or bonding pads) can then be formed on a front-side 40F of the diamond substrate 40 as shown in FIG. 9B. Because the interposer illustrated in FIGS. 9A to 9D is often thin, prior to forming another RDL 45 on the opposite side of the diamond substrate 40, in FIG. 9C, a carrier 47 (e.g., again a glass substrate which is commonly used in fan-out processing) is bonded to the RDL 43 of the interposer through a release layer 49 which can withstand the high temperatures incurred during the formation of the typically polyimide based RDL, and followed by a thinning operation involving CMP and DRIE as needed with or without the use of a sacrificial layer such as silicon dioxide which exposes and reveals the TDVs 41 at the backside 40B of the diamond substrate 40. As shown in FIG. 9D, after formation of the RDL 45, the resultant structure can be mounted on a wafer-mount tape supported by a wafer-mount frame to prepare the structure for dicing, and the carrier 47 can be removed, for example, by shinning a laser at the release layer 49 (or other means including thermo-mechanical shearing), followed by a dicing operation to singulate the diamond substrate 40 so as to obtain diamond interposers of desired dimensions to be used in forming the package structures described herein.

People having ordinary skill in the art shall appreciate that the procedures described in FIGS. 9A to 9D also apply to fabrication of diamond-based or other HTC material-based integrated circuits or other structures, in addition to interposers.

FIGS. 10A to 10D and FIGS. 11A to 11D provide advanced ICs that can be created using diamond-based composite wafers (e.g., bi-wafers and tri-wafers) with diamond placed in close proximity of chip hot spots to quickly spread and dissipate the heat. In FIG. 10A, a full-sized, reconstituted silicon-diamond bi-wafer 50 is first provided, followed by DRIE into the silicon portion, i.e., the device layer, of the bi-wafer 50 using fluorinated gases such as CF₄, SF₆ or xenon difluoride (i.e., the so-called Bosch etch process) as the etch gas to create the through-silicon via (TSV) holes (not shown) and this process can be carried out in conjunction with IC FEOL and BEOL processes of the composite wafer. Subsequently, diamond holes directly underneath the TSV holes can be opened using the process described in FIGS. 9A and 9D to create through-diamond via (TDV) holes in the diamond portion of the bi-wafer 50 underneath the TSV holes, thereby forming the through-silicon-diamond via (TSDV) holes (not shown). Subsequently, one can resume and follow the balance of the diamond interposer process described in FIGS. 9A to 9D from the PECVD, and PVD (e.g., sputtering) steps for passivation and barrier/seed layer deposition, copper (Cu) plating to fill the TSDV holes, CMP to remove the overburden Cu and complete the build of TSDVs 51. As shown in FIG. 10B, RDL 53 can then be formed on a front-side 50F (e.g., surface of the silicon portion) of the bi-wafer 50 connecting to the TSDVs 601. Because the bi-wafer IC in FIGS. 10A to 10D can be very thin, prior to forming another RDL 55 on an opposite side of the bi-wafer 50 as shown in FIG. 10C, a carrier 57 (e.g., a glass substrate which is commonly used in fan-out processing) is bonded to the RDL 53 of the bi-wafer IC through a release layer 59 which can withstand the high temperatures incurred during the formation of the typically polyimide based RDL, followed by a thinning operation involving CMP and DRIE as needed which exposes and reveals the TSDVs 51 on the backside 50B of the bi-wafer 50. In FIG. 10D, after formation of the RDL 55 with proper surface finish and bonding pads (e.g., micro-bumps) and mounting of the resultant structure to a wafer mounting tape/frame, the carrier 57 can be removed by shinning a laser at the release layer 59 or other means including thermos-mechanical shearing, wet cleaning or a combination thereof, and the resultant structure can be diced or singulated by a dicing operation including laser dicing, mechanical dicing, plasma etch, wet etch or a combination thereof to singulate the bi-wafer 50 so as to obtain silicon-diamond ICs or interposers of desired dimensions to be used in the package structures described herein.

Similar operations in FIGS. 10A to 10D can be applied to a tri-wafer scheme as illustrated in FIGS. 11A to 11D, which is more suitable for the formation of, for example, thin processor or memory die containing a thin device layer based on silicon, a thin diamond layer placed in close proximity to the device layer for heat dissipation from chip hot spots and a thicker silicon carrier layer to facilitate thin film processing. In FIG. 11A, a full-sized silicon-diamond tri-wafer 60 (e.g., 12″) including a first silicon portion 62, a diamond portion 64, and a second silicon portion 66 is first provided, followed by DRIE in one of the silicon portions of the tri-wafer 60 using fluorinated gases such as CF₄, SF₆ or xenon difluoride (i.e., the so-called Bosch etch process) as the etch gas to create the through silicon via (TSV) holes (not shown) and this process can be carried out in conjunction with the IC's FEOL and BEOL processing of the composite wafer. Subsequently, the diamond underneath the TSV holes can be opened partially or all the way through using the process described in FIGS. 9A to 9D to create through diamond via (TDV) holes in the diamond portion of the tri-wafer 60 on where the TSV holes are with the assistance of alignment marks as needed, and thereby forming the through silicon-diamond via (TSDV) holes (not shown). One can then resume the balance of the diamond interposer process described in FIGS. 9A to 9D from the PECVD and PVD (e.g., sputtering) steps for passivation and barrier/seed layer deposition, copper (Cu) plating to form the TSDV, CMP and DRIE as needed the overburden Cu to complete the build of TSDVs 61. In FIG. 11B, RDL 63 can subsequently be formed on a front-side 60F of the tri-wafer 60. Because the tri-wafer IC in FIGS. 11A to 11D can be very thin, prior to forming another RDL 65 on the opposite side of the tri-wafer 60, a carrier 67 (e.g., a glass substrate which is commonly used in fan-out processing) is bonded to the RDL 63 of the tri-wafer IC, as shown in FIG. 11C, through a release layer 69 which can withstand the high temperatures incurred during the formation of the typically polyimide based RDLs, the silicon carrier portion 66 of the tri-wafer 60 is removed during the planarization process involving CMP and DRIE as needed with or without the use of a sacrificial layer such as silicon dioxide to reveal the TSDVs. After formation of the RDL 65 on the exposed diamond portion 64 and the TSDVs 61, the carrier 67 can be removed following wafer mounting by shinning a laser at the release layer 69, or other suitable means, as shown in FIG. 11D, followed by a dicing or singulation operation to singulate the ICs so as to obtain silicon-diamond ICs or interposers of desired dimensions to be used in the package structures described herein.

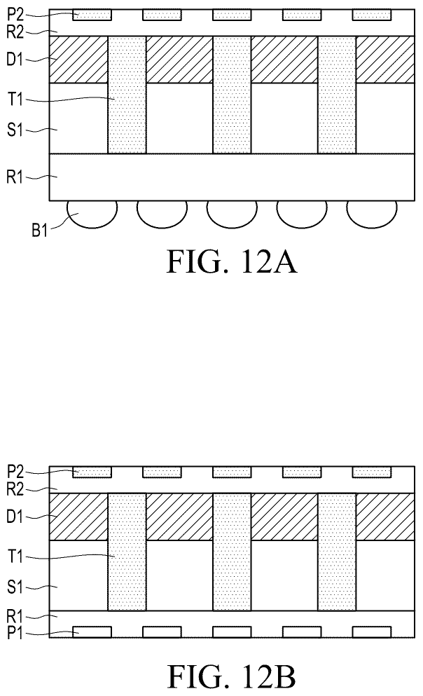

FIGS. 12A and 12B summarize advanced ICs, advanced interposers and advanced spacers that can be created by diamond based composite wafers (i.e., bi-wafers and tri-wafers) including diamond substrate D1 and silicon substrate S1. In FIG. 12A, the advanced IC or advanced interposer is formed with RDL R1 and micro-bumps B1 on one side and RDL R2 and metal pads P2 on another side, while in FIG. 12B, the advanced IC or advanced interposer is formed with RDL R1 and metal pads P1 on one side and RDL R2 and metal pads P2 on another side. Furthermore, through vias Ti (i.e., TSDVs) here can include electrical vias, optical vias, thermal vias, or a combination thereof, whereas RDL R1 and R2 can serve the purposes of not just electrical interconnection but also optical interconnection involving waveguide functions.

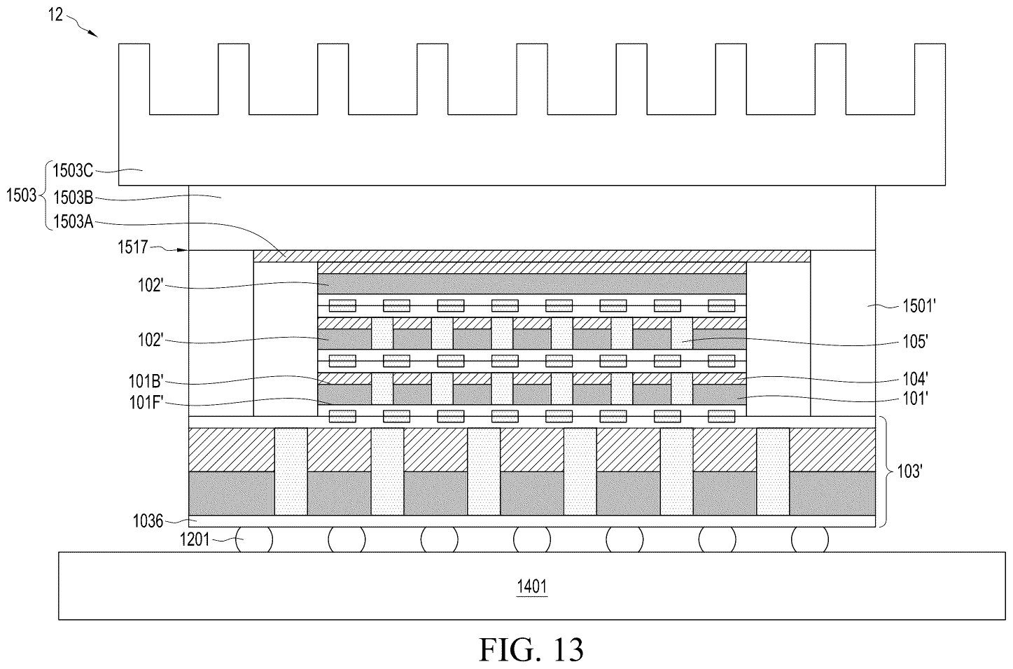

FIG. 13 shows a semiconductor package 12 including a 3D IC structure according to another embodiment of the present disclosure. The difference between the semiconductor package 12 and the semiconductor package 10 in FIG. 4 lies in that the dies 101′ and 102′ of the semiconductor package 12 are built using ICs built based on silicon-diamond composite wafers using the processes shown in FIGS. 10A to 10D and FIGS. 11A to 11D. Taking the die 101′ as an example, the backside 101B′ of the die 101′ (the silicon layer) can be thermally coupled to a supporter 104′, which is the diamond layer and an interposer composed of a material with a thermal conductivity greater than that of silicon, and has a cross sectional width substantially identical to a cross sectional width of the first die 101′. The supporter 104′ and the die 101′ are combined to form a composite layer of a composite wafer based IC with at least one through silicon diamond via (TSDV) 105′ passing through the die 101′ and the supporter 104′ for signal/power transmission and/or enhanced heat dissipation. In some embodiments, the die 101′ and the supporter 104′ can be a composite layer diced from a silicon-diamond composite wafer. The silicon-diamond composite wafer, from which the composite layer in the semiconductor package is diced, can be made of, for instance, silicon-diamond bi-wafers or silicon-diamond-silicon tri-wafers. The dies 101′ and 102′ may be built by the processes shown in FIGS. 10A to 10D and in FIGS. 11A to 11D.

In addition, the semiconductor package 12 may omit the spacers 1511 used in the semiconductor package 10, and thus, the heat transmitted to the supporter 103′ may be dissipated upward to the lid 1503B through the structural member 1501′ (i.e., the vertical leads) that supports the lid 1503B. In the present embodiment, the lid 1503B can be fixed on the structural member 1501′ with the joint 1517 created by bonding, cold welding, etc. In such case, the 3D IC structure in the semiconductor package 12 can be more efficiently cooled by a combination of the supporter 104′ placed in close proximity to chip hot spots, the supporter 103′, the lid 1503B, the HTC layer 1503A, and the heatsink 1503C. In some embodiments, the lid 1503B can be cooled by a capillary vapor phase cooling mechanism using, for example, a vapor chamber. The 3D structure shown in FIG. 13 without the heatsink can be readily extended to liquid immersion cooling by dunking the structure with the lid and the structural member 1501′ on the supporter 103′ in a dielectric coolant or in water with proper surface passivation.

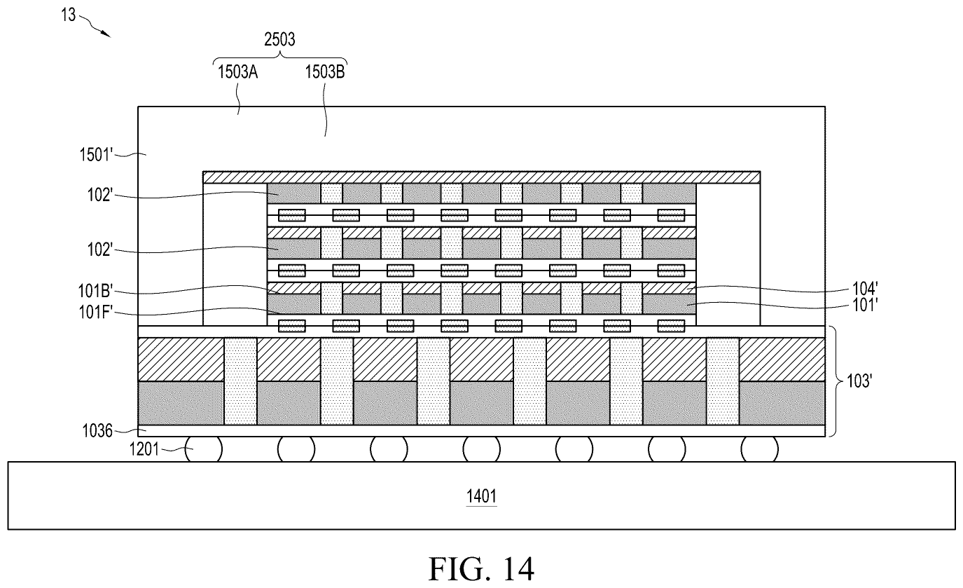

FIG. 14 shows a semiconductor package 13 including a 3D IC structure according to another embodiment of the present disclosure. The difference between the semiconductor package 12 and the semiconductor package 13 is that in order to be better suited for mobile applications, the heat spreader 2503 of the semiconductor package 13 may not include finned heatsink due to the space constraints. Specifically, FIG. 14 shows cooling of a 3D IC structure with the assistance of diamond composite-wafer based ICs, 101′ and 102′, a silicon-diamond or diamond based supporter 103′ and a HTC heat spreader 2503 which can embody a vapor chamber formed as a part of the back cover of the smart handheld devices.

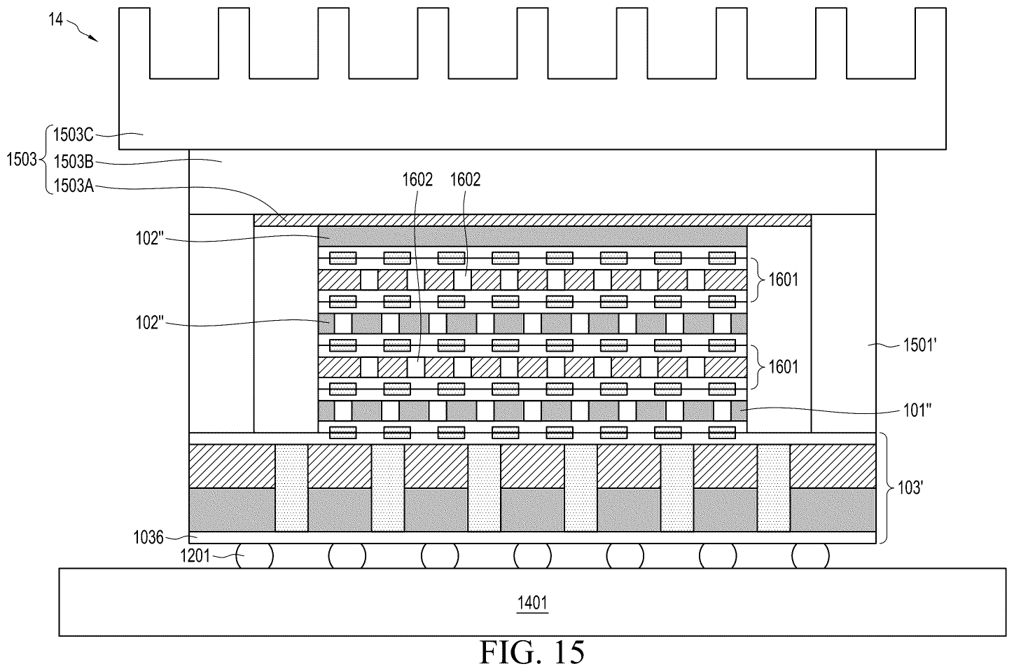

FIG. 15 shows a semiconductor package 14 including a 3D IC structure according to another embodiment of the present disclosure. The difference between the semiconductor package 12 and the semiconductor package 14 lies in that semiconductor package 14 further includes second HTC supporters 1601 between the silicon dies, 101″ and 102″, e.g., between processor die and control dies and/or between the two top silicon dies 102″. The supporter 1601 may include an interposer (e.g., a diamond interposer) composed of a material with a thermal conductivity greater than that of silicon. Also, to enable the signal and power transmission between different layers of dies, through vias 1602 can be formed in and RDLs can be formed on both the top and bottom sides of the supporter 1601, and the supporters 1601 may be bonded with the silicon dies 101″ and 102″ using copper hybrid bonding or flip chip bonding based on micro-bumps. For example, in some embodiments, the supporter 1601 can include a diamond interposer, and the through vias 1602 can be TDVs formed in the diamond interposer supporter 1601, or the supporter 1601 can include a silicon-diamond interposer containing TSDVs.

The semiconductor packages 10, 11, 12, 13, and 14 shown in FIGS. 4, 7, 13, 14, and 15 involve traditional IC processes that create both FEOL and BEOL layers on one side (front-side) of the IC. That is, in the semiconductor packages 10, 11, 12, 13, and 14, the front side 101F of the die 101 (using the semiconductor package 10 in FIG. 4 as an example) is located in close proximity to the supporter 103, and the backside 101B of the die 101 is located farther away from the supporter 103 compared to the front side 101F.

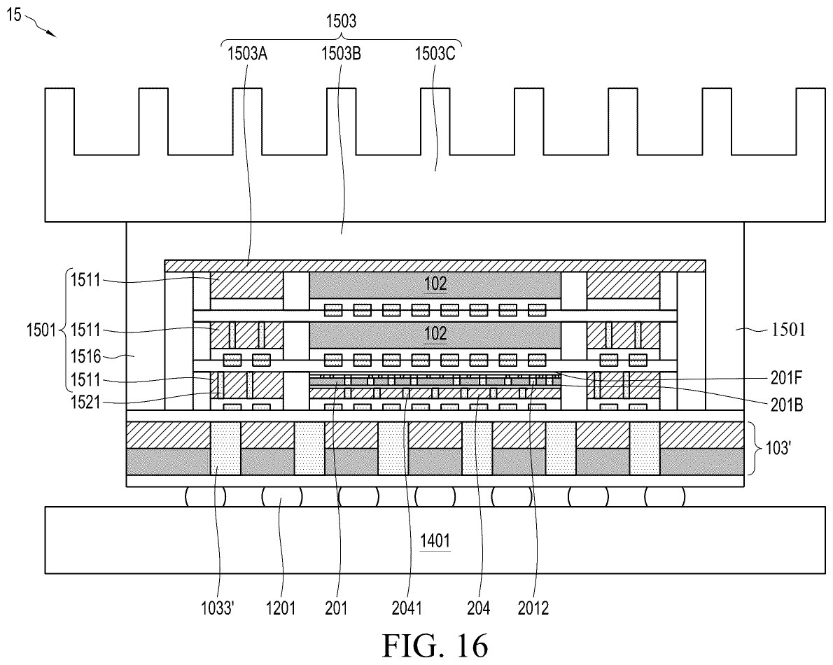

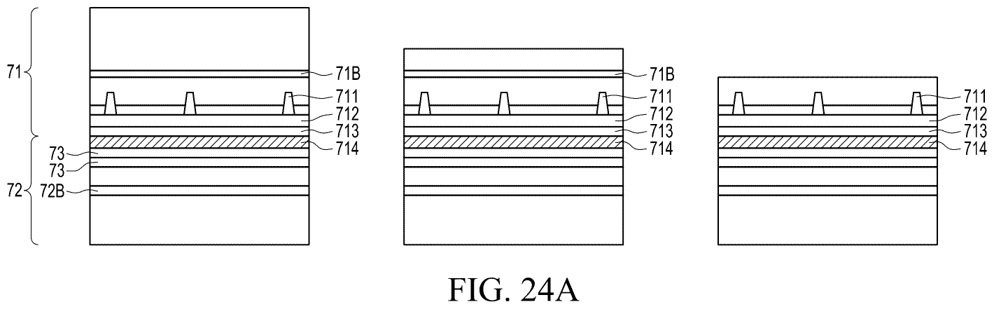

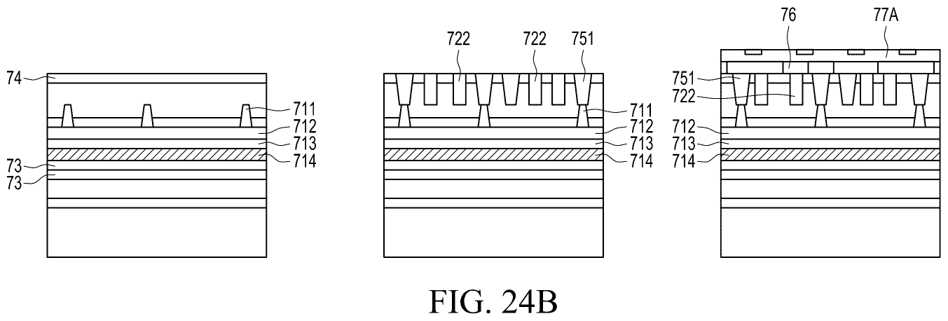

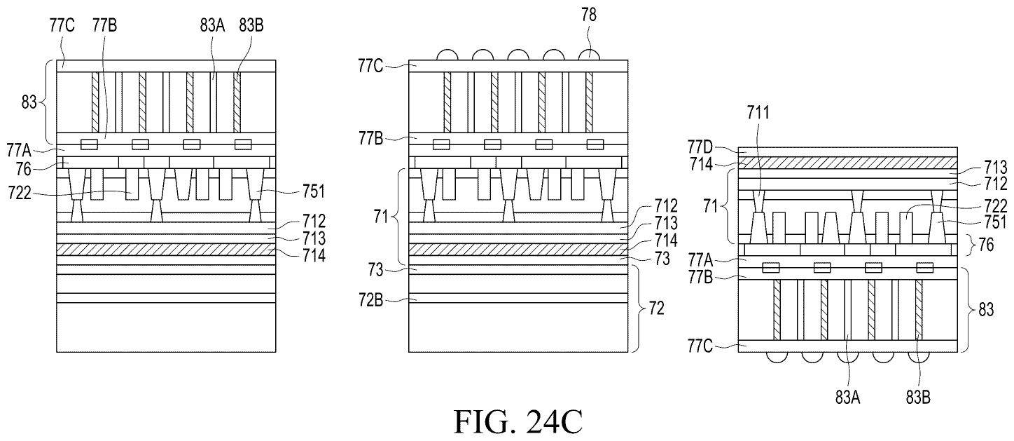

For IC fabrication at the 2 nm node and beyond, backside power delivery network (BSPDN) can be required. This applies to advanced processors for applications covering mobile devices, HPC, data centers and AI. FIG. 16 shows a semiconductor package which is similar to the semiconductor package 10 based on front-side power delivery network (FSPDN) shown in FIG. 4 with the exception that the semiconductor package 15 adopts BSPDN to form the processor die 201. In such case, the BEOL layers will appear on both sides of ultrathin IC 201, i.e., FEOL, local interconnect and intermediate interconnect on the front side and global interconnect on the bottom side with the backside placed in close proximity to the supporter (in sharp contrast to front side in the case of FSPDNs). Furthermore, the die 201 can be cooled with a HTC supporter 204 (e.g., a HTC structure such as a diamond spacer) disposed immediately under the backside of the die 201. The supporter 204 may comprise an interposer composed of a material with a thermal conductivity greater than that of silicon, which can be based on diamond or other HTC materials. Also, the supporter 204 has a cross sectional width substantially identical to a cross sectional width of the processor die 201, and the die 201 and the supporter 204 can be bonded by copper hybrid bonding to the die 201 to form collectively a processor-HTC material combo or a processor-diamond combo using the BSPDN process shown in FIG. 24A to 24C.

As shown in FIG. 16, the die 201 may have its backside 201B located in close proximity to the supporter 204, and its front side 201F located farther away from the supporter 204 compared to the backside 201B. In the present embodiment, the power can be transmitted from the laminate substrate or the PCB 1401 to the devices formed in the FEOL layer of the die 201 through the solder balls 1201, the TSDVs 1033′ in the supporter 103′, the TDVs 2041 in the supporter 204, and the TSVs 2012 (including nano-TSVs) in the die 201.

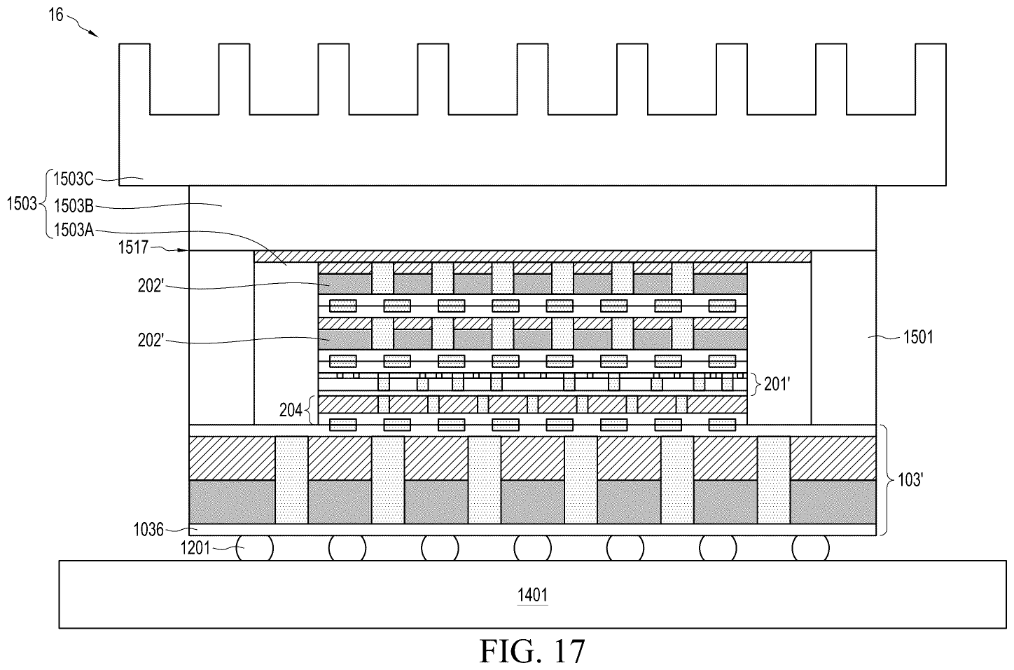

FIG. 17 shows a semiconductor package 16 including a 3D IC structure according to another embodiment of the present disclosure. Although the semiconductor package 16 also adopts a BSPDN for the processor die 201′ as in the case of semiconductor package 15 in FIG. 16, one difference between the semiconductor package 16 and the semiconductor package 15 is that the dies 201′ and 202′ of the semiconductor package 16 may omit the spacers 1511 used in the semiconductor package 15 in FIG. 16. Also, the dies 202′ stacked on the die 201′ may be built by silicon-diamond composite wafers (e.g., bi-wafers and tri-wafers) with TSDVs formed therein so as to achieve better cooling efficiencies.

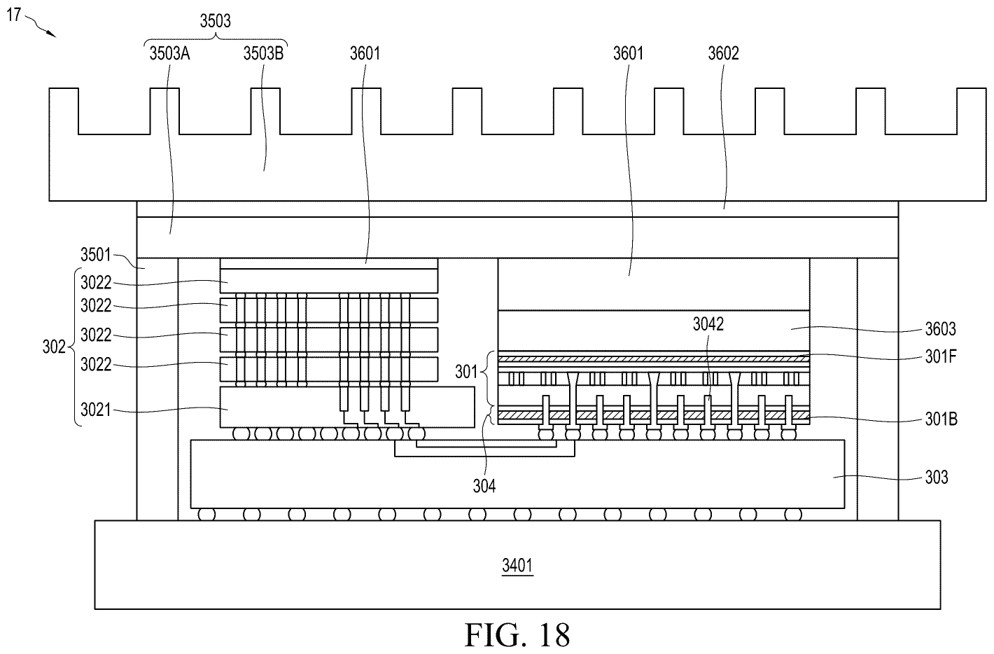

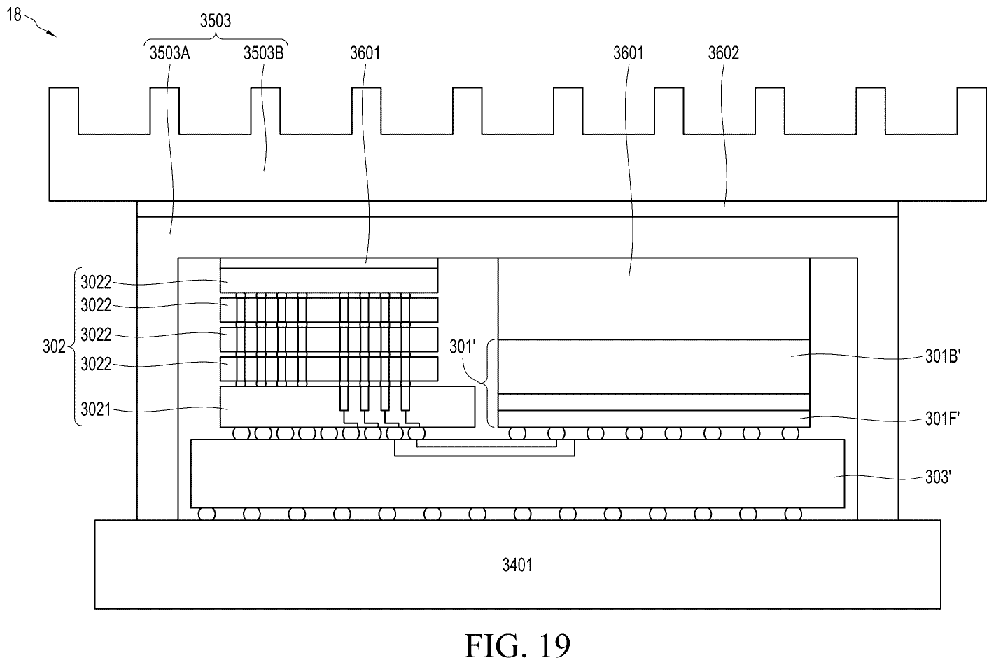

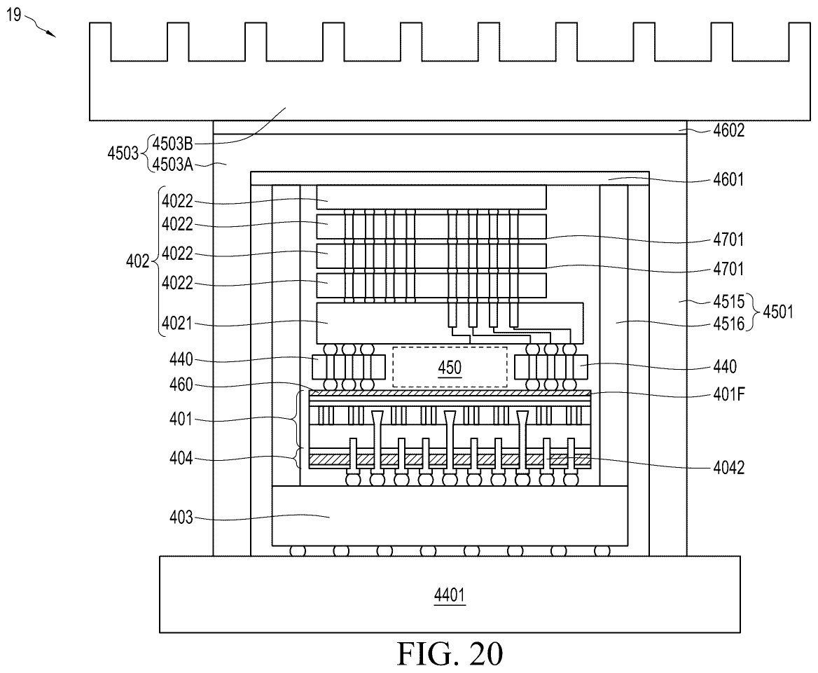

FIG. 18 shows a semiconductor package 17 including a 2.5D IC structure according to another embodiment of the present disclosure. In FIG. 18 where the die 301 (i.e., the processor die) formed on a HTC supporter 304, i.e., the processor-diamond combo with a BSPDN, is mounted side-by-side with at least one 3D DRAM stack 302 (each can include a control die 3021 and DRAM dies 3022) on a HTC supporter 303 which can be a HTC substrate containing an interconnect bridge or a HTC supporter such as a diamond interposer or a silicon-diamond interposer. The supporter 304 may comprise an interposer composed of a material with a thermal conductivity greater than that of silicon, which can be based on diamond, silicon-diamond composite wafers or other aforementioned HTC materials. Furthermore, thermal vias 3042 may also be formed within the silicon die 301 and the diamond supporter 304 for enhanced heat dissipation. It should be noted that: signal interconnects are not shown in FIG. 18 for brevity where only power and thermal vias/interconnects are shown. The same also applies to FIGS. 19 and 20.

As shown in FIG. 18, the processor-diamond combo, i.e., die 301 on the supporter 304, may have its backside 301B located in close proximity to the supporter 304, and its front side 301F located farther away from the supporter 304 compared to the backside 301B. In the present embodiment, the supporter 304 has a cross sectional width substantially identical to a cross sectional width of the processor die 301.

In FIG. 18, the semiconductor package 17 may further include structural members 3501, and a heat spreader 3503 thermally coupled to the structural members 3501 and to the substrate 3401 containing thermal vias and planes or to the HTC supporter 303 (not shown) for enhanced heat dissipation. The heat spreader 3503 may include a metal heat spreader, a vapor chamber (or a cold plate) 3503A and a heatsink (or a manifold) 3503B. The heat spreader 3503A is thermally coupled to the die 301 and the DRAM stack 302 with the use of a HTC TIM 3601 and a HTC material 3603 (e.g., a diamond plate), and to the heatsink 3503B with another HTC TIM 3602. In this package configuration, the heat generated by the die 301 and the DRAM stack 302 can be dissipated upward more efficiency to the heatsink 3503B and downward to the HTC supporter 304 and the HTC supporter 303. In the semiconductor package 18, the HTC material 3603 (e.g., a diamond plate) can be bonded to the front-side (i.e., the FEOL/local interconnect/intermediate interconnect/RDL side) of the die 301 following the aforementioned structures and processes (see, for example, FIG. 5B). The HTC material 3603 and the front side of the die 301 mounted on the supporter 304 can also be adopted as a combo and mounted on top of the supporter 303 as shown in FIG. 18; however, the present disclosure is not limited thereto. In some other embodiments, the HTC material 3603 may be omitted.

FIG. 19 shows a semiconductor package 18 including a 2.5D IC structure according to another embodiment of the present disclosure. The semiconductor package 18 is a counterpart of the semiconductor package 17 shown in FIG. 18 involving traditional ICs based on FSPDN. In such case, the die 301′ may be bonded to the supporter 303′ using its front side 301F′ directly. Furthermore, in the semiconductor package 18, the HTC TIM 3601 can also be replaced by a combination of a HTC material (e.g., a diamond plate) and a TIM as in the case of the semiconductor package 17 shown in FIG. 18.

Referring to FIGS. 18 and 20, the semiconductor package 17 in FIG. 18 includes a 2.5D IC structure containing a processor die with a BSPDN, i.e., the processor-diamond combo, and 3D DRAM stacks 302 disposed side-by-side on the supporter 303, while the semiconductor package 19 in FIG. 20 contains a processor-diamond combo on top of which 3D DRAM 402 stacks are mounted. In FIG. 20, the semiconductor package 19 includes a 3D IC structure according to another embodiment of the present disclosure. The semiconductor package 19 includes a die 401 (e.g., a processor IC), at least one DRAM stack 402 including a control die 4021 and DRAM dies 4022, and a HTC supporter 403 (e.g., a diamond interposer, a silicon-diamond interposer, a HTC laminate substrate, a silicon interposer, or a HTC structure). The DRAM dies 4022 are stacked on the control die 4021, and the control die 4021 can govern the interconnections between the processor die 401 and the memory dies 4022. The DRAM stack 402 is mounted on the processor die 401 with spacer interconnects or spacers 440 in between them, and the processor die 401 mounted on the supporter 404 is disposed on the supporter 403 which is bonded on the laminate substrate or PCB 4401. Though not shown in FIG. 20, the processor die 401 may bear more than one DRAM stack 402, for example, four or six DRAM stacks 402 may be stacked on the processor die 401 according to application which may require implementation of larger spacer interconnects 440.

Also, the semiconductor package 19 further includes an air gap 450, low-thermal-conductivity (LTC) spacer interconnects 440, an optional RDL layer or BEOL layers (e.g., local and intermediate interconnects) 460, a HTC structural member 4501 and a HTC heat spreader 4503. The air gap 450 is defined by the LTC spacer interconnects 440, the processor die 401, and the control die 4021, where the spacer interconnects 440 are disposed between the processor die 401 and the DRAM stack 402 under the control die. In the present embodiment, the LTC spacer interconnects 440 and the air gap 450 can be adopted for thermal isolation (when needed, air gaps 450 can also be created within the BEOL layers for thermal isolation and speed) so as to block the heat from the typically far-high-power processor (e.g., the die 401) compared to memory devices. In some other embodiments, the spacer interconnects 440 can also be made of a HTC material according to application.

The heat spreader 4503 is thermally coupled to the structural members 4501. The heat spreader 4503 includes a heat spreader, such as a cold plate 4503A, and a heatsink (or a manifold) 4503B. The heat spreader 4503A is thermally coupled to the DRAM dies 4022 with a HTC TIM 4601, and the heatsink 4503B can be thermally coupled to the heat spreader 4503A with another HTC TIM 4602.

In addition, the structural member 4501 includes vertical leads 4515 for supporting the heat spreader 4503, and HTC bridges 4516 that can provide thermal paths from the supporter 403 with thermal vias/planes to the heat spreader 4503A and then to the heatsink 4503B of the heat spreader 4503, so that the heat generated by the processor die 401 can be dissipated downward first to the supporter 403, and then upward to the heat spreader 4503 through the HTC bridge 4516.

The RDL 460 contains conductive traces over the front side 401F of the processor die 401, and a thermal isolation layer or a heat spreading layer can be formed in the RDL 460, in a backend-of-line (BEOL) structure proximal to the front side 401F of the processor die 401, and/or in a front-end-of-line (FEOL) structure proximal to the front side 401F of the processor die 401.

In addition, embedded thermal spreading layers 4701 can be formed in the DRAM 402, and similarly, the embedded thermal spreading layers may also be placed in the supporter 403 and/or the other dies and structures, such as the processor die 401, for better thermal dissipation.

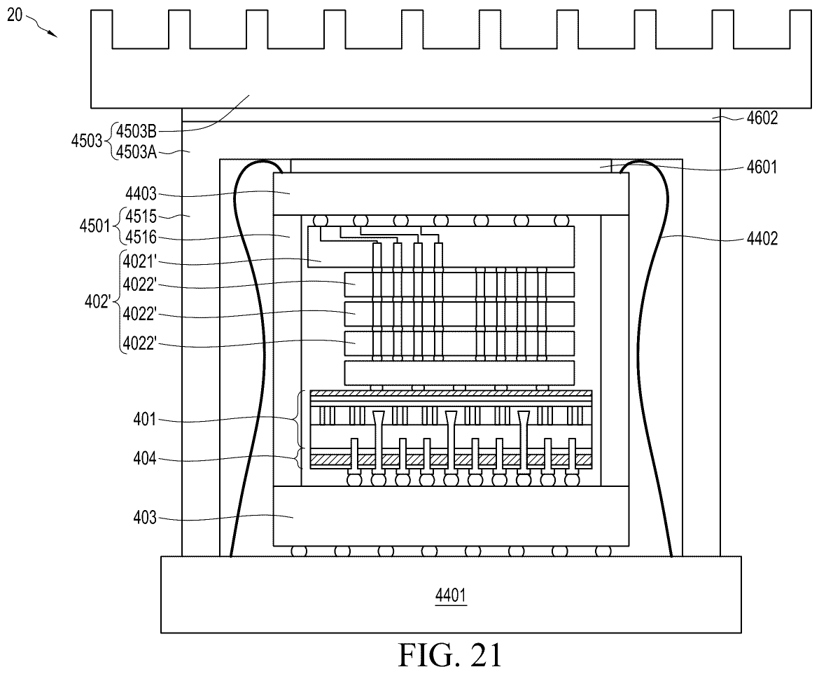

FIG. 21 shows a semiconductor package 20 including a 3D IC structure according to another embodiment of the present disclosure. The semiconductor package 20 has a structure similar to that of the semiconductor package 19; however, in the semiconductor package 20, the processor-diamond combo containing the processor die 401 is powered by a BSPDN as mentioned previously and the DRAM stack 402′ is mounted with the control IC 4021′ sitting on the top of the DRAM stack with the bottom DRAM die 4022′ mounted directly on the processor die 401 and with the control IC powered from the top side. That is, the processor die 401 and the bottom DRAM die 4022′ of the DRAM stack 402′ are interconnected through flip chip bonding based on micro-bumps or copper hybrid bonding. In FIG. 21, the heat spreader 4503 is disposed over structural members 4501 and a circuit layer 4403 (with a HTC material 4601 in between them) which is bonded to the control die 4021′ with the circuit layer 4403 connected to the laminate substrate or PCB 4401 using flexible circuit interconnects (Flexes) 4402. In such case, the laminate substrate or PCB 4401 can support the supporter 403, the processor-diamond combo containing the processor die 401, the memory dies 4022′, and the control dies 4021′.

For the DRAM stack 402′, the power is delivered from the backside (top side in FIG. 21) of the control die 4021′ through the circuit layer 4403, such as a low-coefficient-of-thermal-expansion (CTE), HTC diamond or clad metal (e.g., copper-Invar-copper) interposer, whose CTE can be matched to that of silicon to enhance heat dissipation and reliability, and power (and signal) connectors such as flexible circuit interconnects 4402. Specifically, the flexible circuit interconnects 4402 are electrically connecting the laminate substrate and the PCB 4401 and the circuit layer 4403 proximal to the heat spreader 4503 with the flexible circuit interconnects 4402 being configured to provide power and signal paths to the control die 4021′.

In some embodiments, the circuit layer 4403 can be clad metals, such as copper-invar-copper and copper—Mo—copper possess unique properties. Invar is a Fe—Ni alloy with a 36% nickel content that exhibits the lowest coefficient of thermal expansion (CTE) of known metals and alloys, at for example, 1.2 ppm/° C. between 20° C. and 100° C., and its CTE stays low from the lowest temperatures up to approximately 230° C. By adjusting the thicknesses of copper, core metal (Invar or Mo) and copper, one can get the clad metal's CTE to be close to that of silicon (˜3 ppm/° degree C.), or between that of silicon and PCB (about 12 ppm/° C.). An invar sheet having a thickness of between 0.5 mil and 5 mil, and a layer of electrodeposited copper on at least one side of a thickness between 1 μm and 50 μm has a CTE of 2.8 to 6 ppm/° C. at a temperature between 0° F. and 200° F. In addition, one can adjust the thicknesses of the clad metal layers to achieve a high TC, say 2 to 3 W/cm·K (versus 4 W/cm·K for copper), which is much higher than that of silicon (1.5 W/cm·K).

Flexes based on polyimide dielectrics with multiple, say, 2 metal (copper, Cu) layers can be good interconnect solutions for high-speed applications. Flexes can also be used for interconnecting metal pads in 3D not just on one side face but also metal pads on multiple side faces because Flexes are mechanically formable and bendable. Flexes can provide high-density interconnects (with pitches down to 20 μm and even to 10 μm), DC power distribution, integrated I/Os (inputs and outputs), power distribution, decoupling and electro-magnetic compatibility. All the above good attributes coupled with that Flexes can be tested known-good prior to bonding make Flexes (particularly, adhesive-less Flexes) ideal candidates for 3D interconnections. Take chip-on-film (COF) bonding for liquid crystal display applications for instance, adhesive-less Flexes with Cu leads (which can be pre-plated with tin, Sn) are bonded using thermo-compression bonding (TCB) to, for instance, gold bumps, Sn bumps or tin/copper (Sn/Cu) bumps on glass for applications such as mobiles. A solvent-less epoxy based underfill can be applied following bonding to avoid air bubbles that can be associated with solvent based underfills if not baked properly. Alternatively, a non-conductive adhesive (NCA) or non-conductive paste (NCP) can be applied prior to bonding to glass followed by TCB, in a way similar to fine-pitch flip chip micro-bump assembly. Pre-baking the circuitry prior to Flex bonding can be performed to ensure delamination will not occur. Metal pads on bonded Flexes residing on different side faces can also be interconnected using, for instance, Flexes with leads/pads containing palladium (Pd) passivation for Flex-to-Flex bonding at low-temperatures such as 140° C.

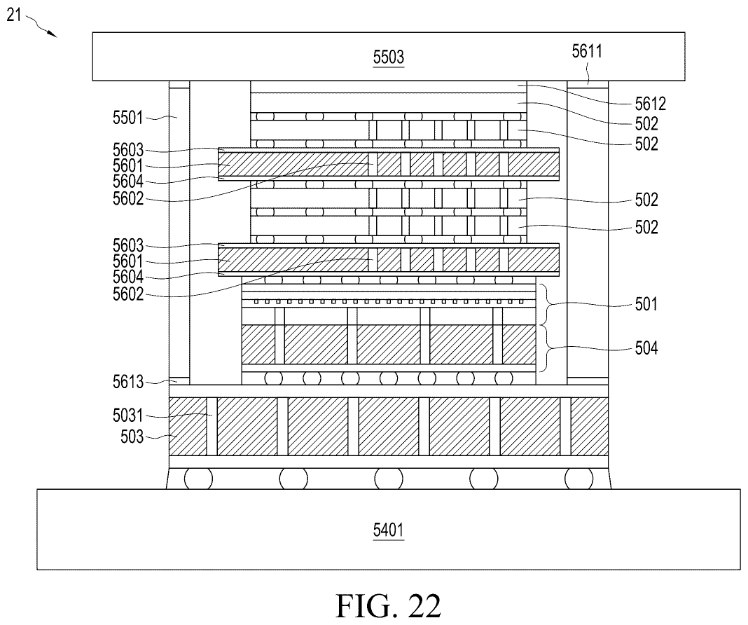

FIG. 22 shows a semiconductor package 21 including a 3D IC structure according to another embodiment of the present disclosure. The semiconductor package 21 has a structure similar to that of the semiconductor package 14 involving FSPDNs (see FIG. 15); with the semiconductor package 21 containing supporters 5601 disposed between the processor die 501 and the die 502 and between the two adjacent dies 502 in the vertical direction. In some embodiments, the one or more dies 502 referred herein includes control die 502 and memory die 502 in the DRAM die stack, and with a control die 502 disposed at the bottom of the one or more memory dies 502. The supporter 5601 may also be referred as a HTC structure that includes an interposer composed of a material with a thermal conductivity greater than that of silicon (e.g., a diamond interposer or a silicon-diamond interposer), thereby facilitating heat dissipation. The supporter 5601 may have a cross sectional width greater than or substantially identical to a cross sectional width of the processor die 501 or adjacent memory dies 502.

Furthermore, the semiconductor package 21 further includes through vias 5602 formed in the supporter 5601, a RDL 5603 formed on a first side of the supporter 5601, and a RDL 5604 formed on a second side of the supporter 5601 opposite to the first side where the RDLs, 5603 and 5604, can be electrically connected by the through vias 5602, thereby allowing signal and power transmission and enhanced heat dissipation involving the processor die 501 and the control and memory dies 502.

In the semiconductor package 21, the processor die 501 can be a die with a FSPDN formed using a diamond-silicon composite wafer and with the die containing a silicon or an active IC portion and a diamond supporter portion 504, and the silicon portion on the supporter 504 is mounted on a HTC supporter 503. Alternatively, the diamond portion 504 can be placed on top of the silicon portion of the processor-diamond combo in the semiconductor package 21.

The semiconductor package 21 further includes structural members 5501 and heat spreader 5503. The heat spreader 5503 is thermally coupled to the structural members 5501 with a HTC thermal interface material (TIM) 5611, and the heatsink 5503 can also be thermally coupled to the memory dies 502 with another HTC TIM 5612. Also, the structural members 5501 can include diamond spacers that are thermally coupled to the supporter 503 with TIMs 5613. The supporter 503 may include an interposer composed of a material with a thermal conductivity greater than that of silicon interposer material. For example, the supporter 503 may include a diamond interposer with TDVs 5031 formed therein so as to enable signal/power transmission and enhanced heat dissipation. In some embodiments, the supporter 503 can be composed of diamond, silicon, graphene, boron nitride, boron arsenide, cubic boron arsenide, aluminum nitride, silicon carbide or a combination thereof.

The supporter 503 is mounted on the laminate substrate or the PCB 5401. As a result, the supporter 503 and the structural members 5501 (e.g., the diamond spacers) can provide heat dissipation paths from the bottom of the die 501 to the supporter 504 and then to the supporter 503, the structural member 5501 and the heat spreader 5503 besides heat dissipation in the upward direction, enhanced due to the presence of the supporters 5601. In some embodiments, the heat spreader 5503 can include a diamond heatsink, a vapor chamber, a TIM or a combination thereof according to the system requirements.

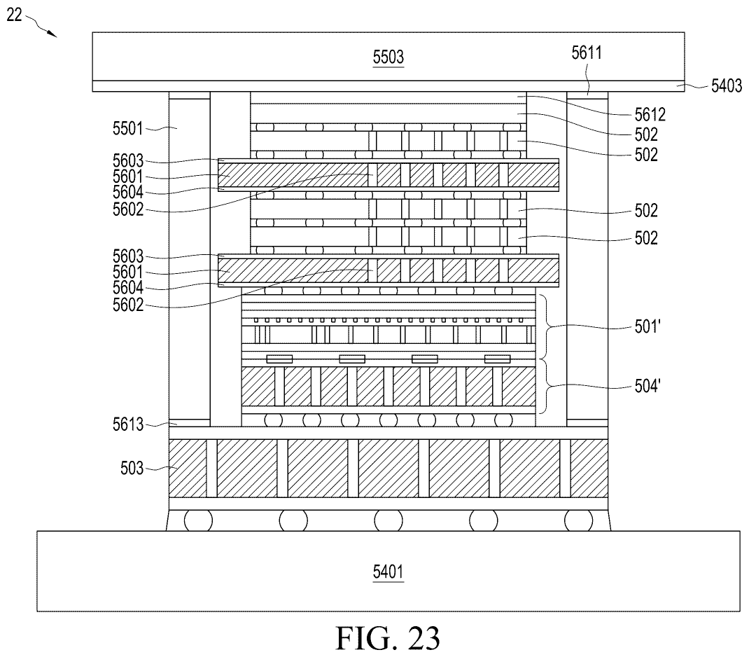

FIG. 23 shows a semiconductor package 22 including a 3D IC structure according to another embodiment of the present disclosure. The semiconductor package 22 has a structure similar to that of the semiconductor package 21. However, unlike the processor die 501 and the supporter 504 in the semiconductor package 21 that are built using composite wafers, the processor die 501′ and the supporter 504′ under the processor die 501′ together form a processor-diamond combo using processes described in FIGS. 24A to 24C below.

FIGS. 24A to 24C show a process flow to create the BSPDN structure enhanced with a HTC supporter such as a diamond interposer or an interposer based on other high-TC materials without the second silicon substrate such that the second silicon substrate side of the HTC-processor combo can be mounted with the DRAM stacks with or without the use of a RDL. In FIG. 24A, a first semiconductor substrate 71 is bonded to a second semiconductor substrate 72 through a pair of bonding layers 73, for example, a dielectric bonding layer. Optionally, each of the first semiconductor substrate 71 and the second semiconductor substrate 72 includes a respective etching stop layer, 71B or 72B, between the active regions and the bulk regions. In the first semiconductor substrate 71, a buried power rail 711 is formed in conjunction with a front-end-of-line (FEOL) structure 712 of the processor IC, which is later stacked with a local interconnect 713 and an intermediate interconnect 714 (and optionally a RDL between the intermediate interconnect 714 and the bonding layers—not shown). The local interconnect 713 and the intermediate interconnect 714 can be a portion of a back-end-of-line (BEOL) structure of the processor IC with distinguishable line width and line spacing. The second semiconductor substrate 72 is typically attached to the intermediate interconnect 714 through the bonding layers 73 for structural integrity since the first semiconductor substrate 71 used in building the processor IC with a BSPDN will be subsequently thinned to less than 5 μm by suitable wafer grinding/thinning operations, chemical mechanical polishing (CMP) operations, dry and/or wet etch operations, or a combination thereof. Additional wet etch and planarization operations may be carried out to remove the first silicon substrate and the etching stop layer 71B while leaving the active region with the power rail intact.

In FIG. 24B, a backside passivation 74 is deposited by, for example, thermal oxidation or PECVD operation, thereby forming a layer of silicon oxide 74. Nano-TSVs 751 are then formed at the backside of the processor IC to establish electrical connections with the buried power rail 711. Thermal vias 722 may also be formed on the backside of the processor IC at various locations proximal to the heat sources, for example, to the FEOL structure 712, the nano TSVs 751, and/or the buried power rail 711. A global interconnect 76, which is devised to provide power and signaling to the processor IC through its backside, can then be formed over the nano-TSVs 751 and the thermal vias 722, in conjunction with the formation of an optional RDL 77A on the backside of the processor IC. The global interconnect 76 is a general term that includes power traces and signal traces routed to the FEOL 712 structure of the processor IC.

In FIG. 24C, a supporter 83, for example a diamond interposer or any other suitable HTC-based component, with an RDL 77B on a first side 831 facing backside of the processor IC and an RDL 77C on a second side 832 opposite to the first side 831, is then bonded through copper hybrid bonding based on, for example, oxide-to-oxide bonding to the processor IC through the RDL 77A previously formed thereon. The bonding layers hereby connecting the supporter 83 to the processor IC can be hybrid bonding layers. The supporter 83 or the diamond interposer in some embodiments may possess a plurality of TDVs serving distinguishable purposes. For example, a thermal via 83A in the supporter 83 connecting the RDL 77B and RDL 77C is thermally coupled to the thermal vias 722 previously formed in the processor IC. For another example, a power via and a signal via 83B (collectively a power/signal via) in the supporter 83 connecting the RDL 77B and RDL 77C is electrically connected to the power traces and signal traces of the global interconnect 76 and then to the FEOL 712 structure of the processor IC. Contact terminals 78 such as micro-bumps can be formed on the RDL 77C of the supporter 83. In the next step, the second semiconductor substrate 72, including the bulk semiconductor, the etching stop layer 72B, and the bonding layers 73, is removed by suitable planarization and etch operations, followed by formation of RDL 77D as needed over the intermediate interconnect 714 exposed after the removal of the second semiconductor substrate 72.

In some embodiments, the processor die 501′ and the supporter 504′ in FIG. 23, for instance, can be formed with a BSPDN by the processes shown in FIGS. 24A to 24C, and thus, the processor die 501′ and the supporter 504′ can have the same structures as the semiconductor substrate 71 and the supporter 83. Furthermore, in some embodiments, the die 201 and the supporter 204 shown in FIG. 16 as an additional example may also be formed by the processes shown in FIGS. 24A to 24C.

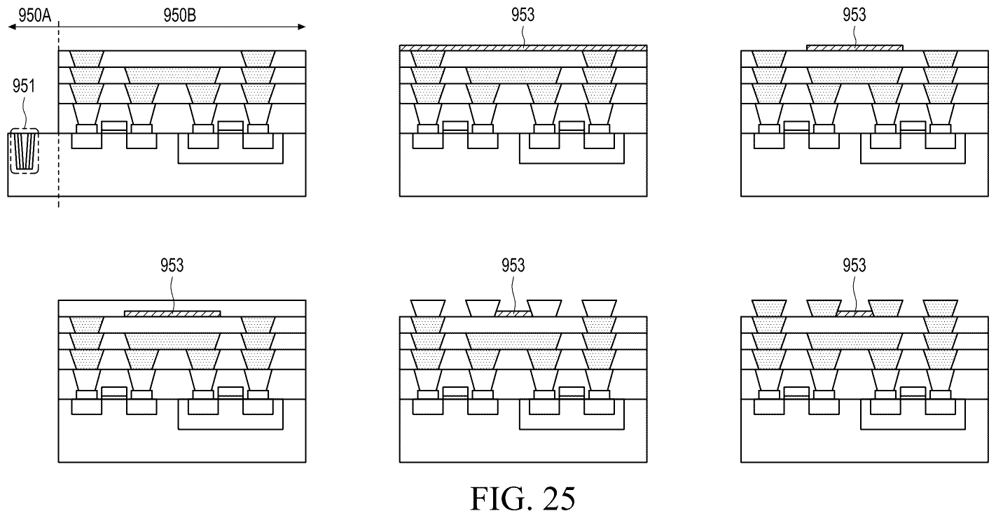

FIG. 25 shows manufacturing operations to form a thermal isolation layer or structure, and/or a thermal spreading layer or structure in suitable interconnect layers of the semiconductor packages described herein. A thermal isolation layer or structure 951 can be formed adjacent to predetermined active regions, for example, between a memory cache region 950A and a hot core region 950B of a processor IC, in a form of one or more trenches or holes and prior to or during the IC FEOL processing. In some embodiments, the thermal isolation layer 951 can include a thermal metamaterial structure such as silica/graphene/Si/graphene/silica trenches (see 951 in FIG. 25) created during FEOL processing or multi-layer hetero-structures containing ultra-thin (e.g., 2 nm) nano-materials such as graphene on MoSe₂, MoS₂ and WSe₂ deposited by vacuum processes in isolation trenches for better heat management. A thermal metamaterial structure such as graphene on MoSe₂, MoS₂ and WSe₂ hetero-structures can possess high thermal isolation property with thermal resistance greater than 100 times of SiO₂ in comparable thickness and effective thermal conductivity lower than air at room temperature. In addition, the thermal isolation layer and/or a thermal spreading layer 953 can be deposited in BEOL structures in a form of conductive traces or a three dimensional meta-material structure. Heat spreading materials can include graphene, carbon nanotube, diamond, boron nitride and/or boron arsenide. The thermal isolation layer and/or a thermal spreading layer 953 can then be patterned by suitable lithography operations, and be encapsulated by suitable dielectric material, and routed with connection to thermal vias through proper lithography operations such as via hole/hole patterning in dielectric layer and contact metallization. Referring to FIGS. 24C and 25, the thermal isolation layer and/or a thermal spreading layer illustrated in FIG. 25 can be formed in the RDL 77D, BEOL structures of the processor IC such as the local interconnect 713, and the intermediate interconnect 714 proximal to the front side of the processor IC, the FEOL structure 712 of the processor IC, and/or in the global interconnect 76 proximal to the backside of the processor IC.

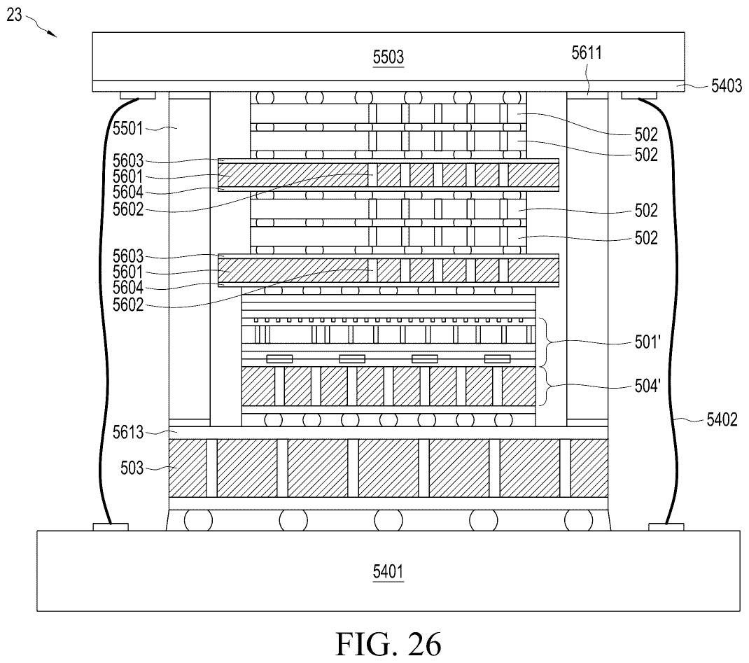

FIG. 26 shows a semiconductor package 23 including a 3D IC structure according to another embodiment of the present disclosure. The semiconductor package 23 has a structure similar to that of the semiconductor package 22; however, the semiconductor package 23 further includes a circuit layer 5403 and flexible circuit interconnects 5402. The circuit layer 5403 is electrically coupled to the control die 502, and the flexible circuit interconnects 5402 are electrically connected to the laminate substrate or the PCB 5401. The circuit layer 5403 is proximal to the heat spreader 5503 with the flexible circuit interconnect 5402 being configured to provide power and signal paths to primarily the control IC and memory dies 502.

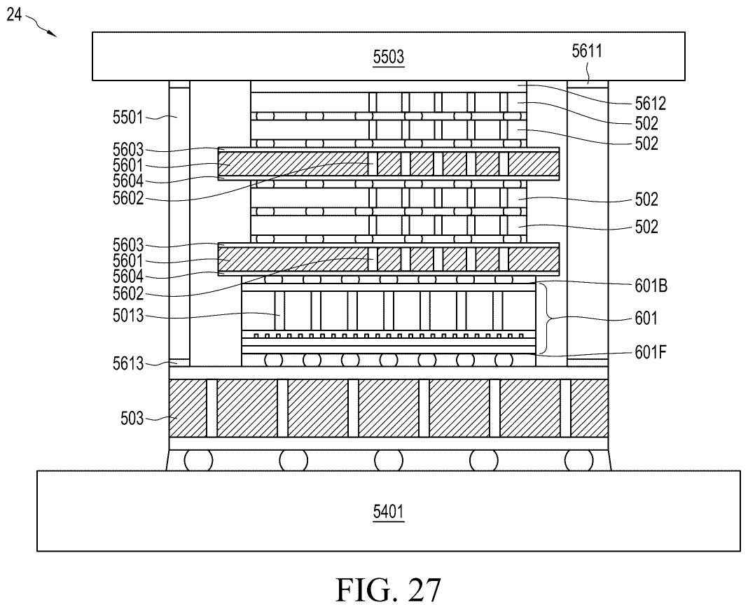

FIG. 27 shows a semiconductor package 24 including a 3D IC structure according to another embodiment of the present disclosure. The semiconductor package 24 has a structure similar to that of the semiconductor package 21; however, the processor die 601 is powered by a front side power delivery network (FSPDN). That is, the processor die 601 may have its front side 601F (the FEOL/BEOL side) located in close proximity to the supporter 503, and its back side 601B located farther away from the supporter 503 compared to the front side 601F.

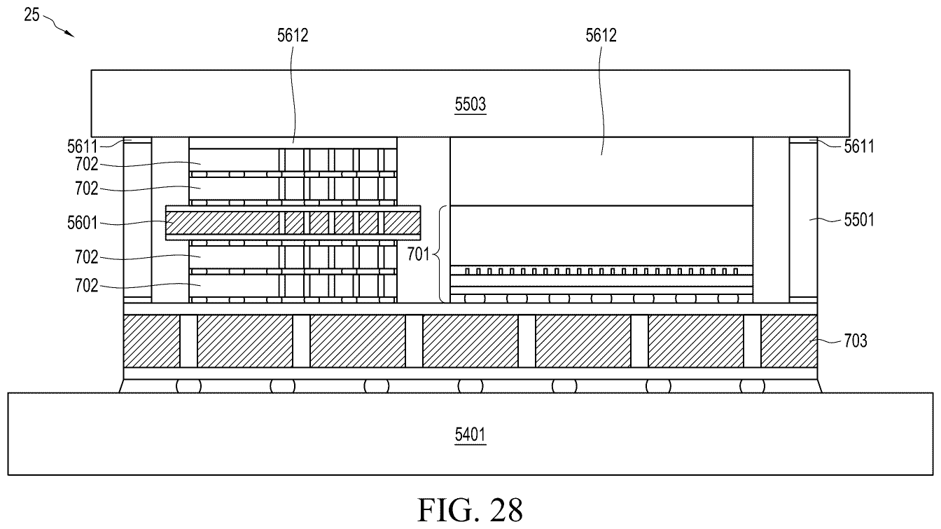

FIG. 28 shows a semiconductor package 25 including a 2.5D IC structure according to another embodiment of the present disclosure. The semiconductor package 25 has a structure similar to that of the semiconductor package 24. That is, both semiconductor package 25 and semiconductor package 24 are powered by FSPDNs; however, unlike the 3D IC structure adopted by the semiconductor package 24, the processor die 701 and the DRAM stack including dies 702 in the semiconductor package 25 are disposed side-by-side on the supporter 703 in the 2.5D IC structure.

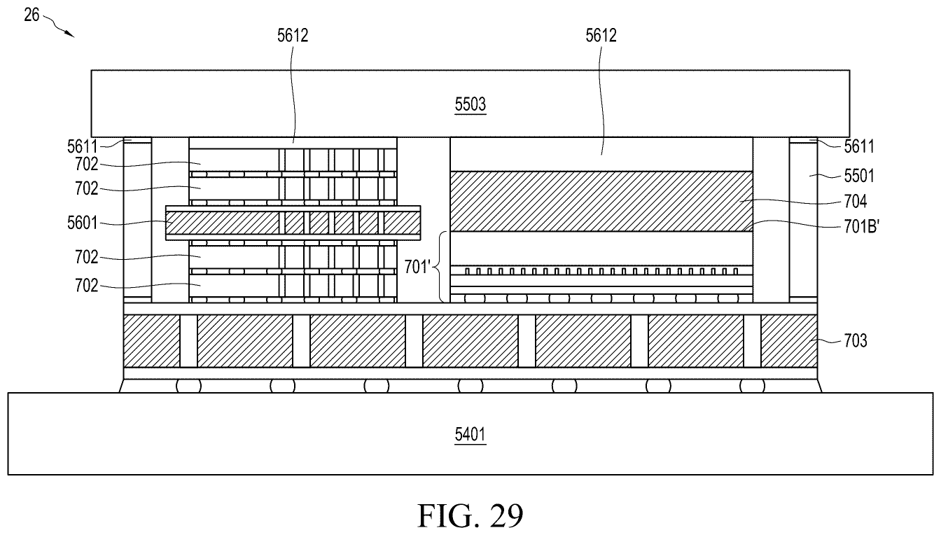

FIG. 29 shows a semiconductor package 26 including a 2.5D IC structure according to another embodiment of the present disclosure. The semiconductor package 26 has a structure similar to that of the semiconductor package 25; however, the processor die 701′ can be built by a silicon-diamond composite wafer so that the backside 701B′ (opposite to the FEOL/BEOL side) of silicon layer of the processor die 701′ can be thermally coupled to a diamond supporter 704, thereby facilitating heat dissipation.

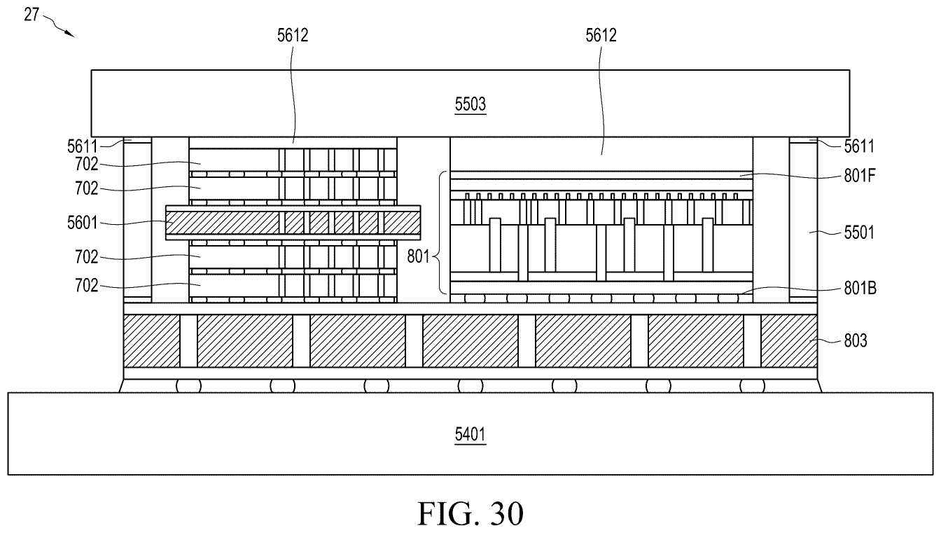

FIG. 30 shows a semiconductor package 27 including a 2.5D IC structure according to another embodiment of the present disclosure. The semiconductor package 27 has a structure similar to that of the semiconductor package 25; however, the semiconductor package 27 adopts a BSPDN for the processor die 801. In such case, the processor die 801 may have its backside 801B located in close proximity to the supporter 803, and its front side 801F located farther away from the supporter 803 compared to the backside 801B.

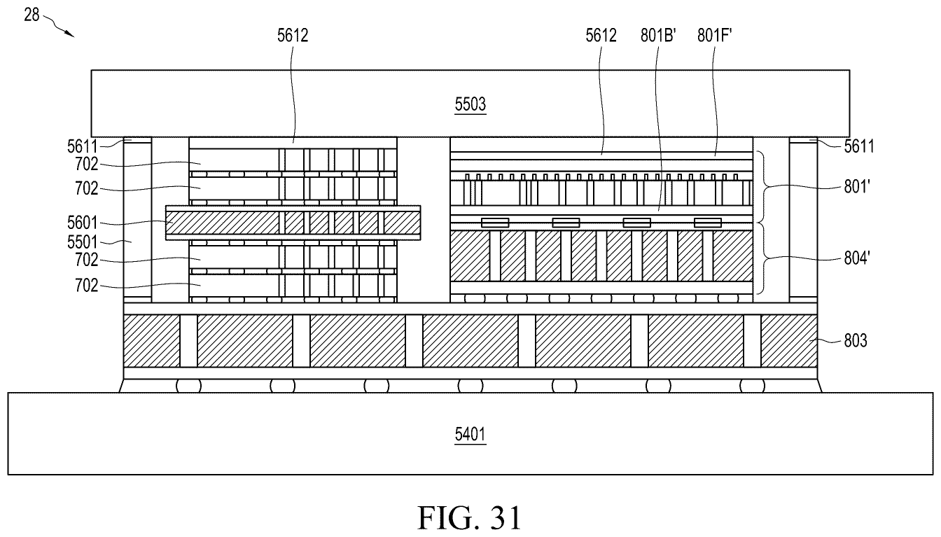

As shown in FIG. 30, the processor die 801 can be built based on silicon, however, the present disclosure is not limited thereto. FIG. 31 shows a semiconductor package 28 including a 2.5D IC structure according to another embodiment of the present disclosure. The semiconductor package 28 has a structure similar to that of the semiconductor package 27; however, the processor die 801′ with a BSPDN is bonded to a diamond supporter 804′ by, for example, copper hybrid bonding. That is, the semiconductor package 28 adopts the structure of processor-diamond combo which can be formed by the process flow shown FIGS. 24A to 24C previously.

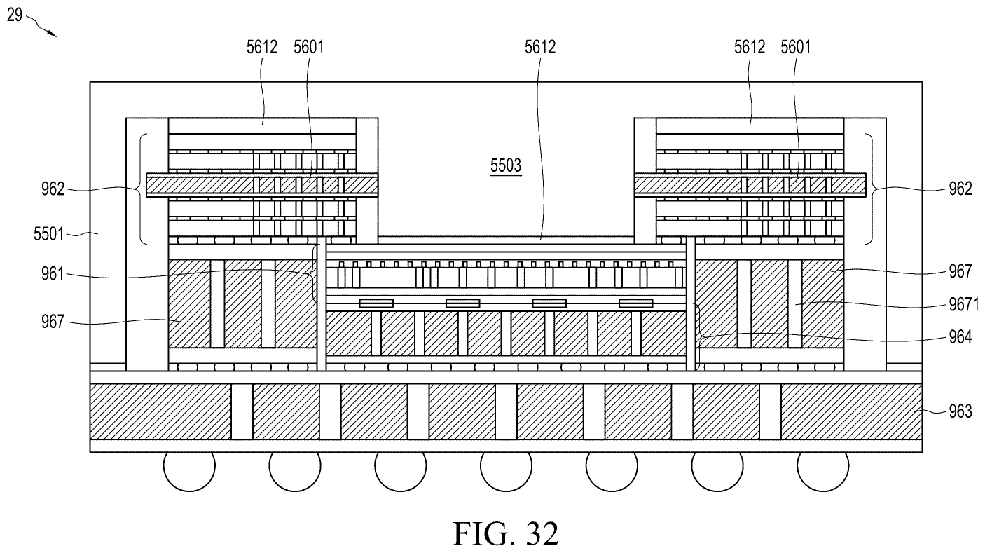

FIG. 32 shows a semiconductor package 29 including a 2.5D IC structure according to another embodiment of the present disclosure. The semiconductor package 29 has a structure similar to that of the semiconductor package 28. For example, the processor die 801′ and the diamond supporter 804′ in the semiconductor package 28, and a processor die 961 and a supporter 964 in the semiconductor package 29 form two processor-diamond combos with a BSPDN. However, in the semiconductor package 29, the two DRAMs 962 are partially stacked on the processor die 961. Specifically, the DRAMs 962 are disposed on the processor die 901 and the diamond spacers 967 with TDVs 9671 formed therein. In addition, the diamond spacers 967 and the processor-diamond combo structure (including the processor die 961 and the supporter 964) are disposed on another HTC supporter 963 with conductive traces formed therein, and thus, signal and power transmission and downward heat dissipation can be enabled through the supporter 963. The supporter 963 may include an interposer composed of a material with a thermal conductivity greater than that of silicon interposer material. For example, the supporter 963 may include a diamond interposer with TDVs formed therein so as to improve the cooling efficiencies. In some embodiments, the supporter 963 can be composed of diamond, silicon, graphene, boron nitride, boron arsenide, cubic boron arsenide, aluminum nitride, silicon carbide or a combination thereof.

The 3D IC and 2.5D IC structures described herein all allow dual-sided or multi-sided cooling from the top side and the bottom side of the 3D IC and 2.5D IC structures while some 3D IC structures enable skip-die, dual-sided or multi-sided signal and power distributions, i.e., power and signal can now be supplied directly from the bottom die or the interposer supporting the bottom die on the bottom-side to not just the die directly above but also to all other dies in the die stack in addition to the traditional one-sided interconnection from the bottom die (to the die directly above and then from the die above to yet another die above, one-die-at-a-time, etc.), and from the top side of the 3D IC structure (e.g., to the control IC) to the dies below in the 3D IC structures

In addition, the dies shown in the figures of the present disclosure can be single die or combinations of ICs or chiplets interconnected by, for example, wafer-level fan-out, 2.5D IC and 3D IC processes in the same package tier of 3D stack. Each tier can also incorporate passives and other active components. In all cases, HTC TIMs can help alleviate thermal issues.

Also, in all figures, when micro-bumps are used, non-conductive paste/film is needed (but not shown) to fill the interstices between the two components being flip chip bonded. Also, in order to go finer pitches, flip chip bumps, particularly those between two ICs, can be replaced by copper hybrid bonds. The 3D IC and 2.5D IC structures disclosed also can be molded (which may not be shown in the figures) to enhance the structural integrity of these structures.

One aspect of the present disclosure provides a semiconductor package. The semiconductor package includes a first die and a first supporter. The first die has a front side and a backside. The first supporter is disposed immediately under the first die and thermally coupled to the first die. The thermal conductivity of the first supporter is greater than the thermal conductivity of the first die.

Another aspect of the present disclosure provides a semiconductor package. The semiconductor package includes a processor die, a first high thermal conductivity (HTC) structure, a plurality of memory dies and control dies, and a second HTC structure. The processor die has a front side and a backside. The first HTC structure is disposed immediately under the processor die and thermally coupled to the processor die. The thermal conductivity of the first HTC structure is greater than the thermal conductivity of the processor die. The memory dies and the control dies are stacked over the processor die. The second HTC structure are disposed between the processor die and control dies, or between adjacent memory dies. The thermal conductivity of the second HTC structure is greater than the thermal conductivity of the processor die.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor package, comprising:
a first die having a front side and a backside; and
a first supporter disposed immediately under the first die and thermally coupled to the first die,
wherein a thermal conductivity of the first supporter is greater than a thermal conductivity of the first die.

2. The semiconductor package of claim 1, wherein the first supporter comprises an interposer composed of a material with a thermal conductivity greater than that of silicon, and with the interposer having a cross sectional width greater than or substantially identical to a cross sectional width of the first die.

3. The semiconductor package of claim 1, wherein the first supporter and the first die are combined to form a composite layer with at least one via passing through the first die and the first supporter.

4. The semiconductor package of claim 1, wherein the first supporter is composed of diamond, graphene, boron nitride, boron arsenide, cubic boron arsenide, aluminum nitride, or silicon carbide.

5. The semiconductor package of claim 1, wherein the backside of the first die is located in close proximity to the first supporter and the front side of the first die is farther away from the first supporter compared to the backside, and the semiconductor package further comprises:
a global interconnect disposed on the backside of the first die; and
a first re-distribution layer (RDL) disposed on the global interconnect; and
a second RDL on a first side of the first supporter facing the first die;
wherein the first die and the first supporter are bonded through the first RDL and the second RDL.

6. The semiconductor package of claim 5, further comprising:
a third RDL on a second side of the first supporter opposite to the first side;
a first thermal via in the first supporter, connecting the second RDL and the third RDL; and
a first power via and a first signal via in the first supporter, connecting the second RDL and the third RDL.

7. The semiconductor package of claim 6, further comprising:
a buried power rail proximal to a front-end-of-line (FEOL) structure of the first die;
a power trace and a signal trace in the global interconnect, electrically connected to the buried power rail and to the FEOL structure, respectively; and
a second thermal via proximal to the power and signal trace in the global interconnect and the FEOL structure of the first die, wherein the second thermal via is thermally coupled to the first thermal via in the first supporter.

8. The semiconductor package of claim 6, further comprising:
a fourth RDL containing conductive traces over the front side of the first die,
wherein a heat spreading layer or a thermal isolation layer is formed in the fourth RDL, in a back-end-of-line (BEOL) structure proximal to the front side of the first die, in the global interconnect of the first die, or in a front-end-of-line (FEOL) structure proximal to the front side of the first die.

9. The semiconductor package of claim 1, further comprising:
a plurality of second dies stacked over or disposed side-by-side with the first die;
a structural member disposed side-by-side with the first die and the second dies; and
a heat spreader disposed over the first die, the plurality of the second dies, and the structural member,
wherein the structural member is thermally coupled with the first supporter and the heatsink, and the structural member possesses a thermal conductivity greater than the thermal conductivity of the first die.

10. The semiconductor package of claim 9, wherein the structural member comprises (1) a plurality of interposers composed of a material with a thermal conductivity greater than that of silicon with through vias; (2) a spacer interconnect composed of a material with a thermal conductivity lower than that of silicon with or without a through via; (3) a vertical lead of the heat spreader; or a combination thereof.

11. The semiconductor package of claim 9, wherein the heat spreader comprises a metal lid, an integrated heat spreader, a planar heatsink, a fin-type heatsink, a vapor chamber, a cold plate, a manifold, an interposer or a combination thereof, with the heat spreader thermally coupled to the structural member with or without a thermal interface material (TIM) having a thermal conductivity greater than that of silicon.

12. The semiconductor package of claim 9, further comprising:
a second supporter between the first die and one of the second dies, or between adjacent second dies, wherein the second supporter comprises an interposer composed of a material with a thermal conductivity greater than that of silicon; and
a through via in the second supporter.

13. The semiconductor package of claim 12, further comprising:
a heat spreading layer or a thermal isolation layer in respective interconnect structure of the first supporter, the second supporter, the second dies, or a combination thereof.

14. The semiconductor package of claim 12, wherein the second supporter further comprises:
a fifth RDL on a first side of the second supporter; and
a sixth RDL on a second side of the second supporter opposite to the first side,
wherein the through via electrically or optically connects the fifth RDL and the sixth RDL.

15. The semiconductor package of claim 1, wherein the backside of the first die is located in close proximity to the first supporter and the front side of the first die is farther away from the first supporter compared to the backside, and the semiconductor package further comprising:
a plurality of second dies stacked over or disposed side-by-side with the first die;
a second supporter between the first die and one of the second dies, or between adjacent second dies;
a structural member disposed side-by-side with the first die and the second dies with the structural member having a thermal conductivity greater than the thermal conductivity of the first die;
a heat spreader over the plurality of second dies and the first die with the heat spreader thermally coupled to the structural member;
a carrier supporting the first die, the first supporter, the second dies, and the second supporter; and
a flexible circuit interconnect electrically connecting the carrier or the first supporter to a circuit layer proximal to the heat spreader with the flexible circuit interconnect configured to provide power and signaling to one of the second dies or the front side of the first die.

16. A semiconductor package, comprising:
a processor die having a front side and a backside;
a first high thermal conductivity (HTC) structure disposed immediately under the processor die and thermally coupled to the processor die, wherein a thermal conductivity of the first HTC structure is greater than a thermal conductivity of the processor die;
a plurality of memory dies and control dies stacked over the processor die; and
a second HTC structure between the processor die and control dies, or between adjacent memory dies, wherein a thermal conductivity of the second HTC structure is greater than the thermal conductivity of the processor die.

17. The semiconductor package of claim 16, wherein the first HTC structure and the processor die combined to form a composite wafer with at least one via passing through the processor die and the first HTC structure.

18. The semiconductor package of claim 16, further comprising:
a buried power rail proximal to a front-end-of-line (FEOL) structure of the processor die; and
a power trace and a signal trace in an interconnect proximal to the backside of the processor die,
wherein the power trace and the signal trace are electrically connected to the buried power rail and the FEOL structure, respectively, and are configured to provide power and signaling to the processor die from the backside of the processor die.

19. The semiconductor package of claim 18, further comprising:
spacer interconnects between the processor die and the plurality of memory dies and control dies;
an air gap defined by the spacer interconnects, the processor die, and the control dies, wherein the control dies govern the interconnections between the processor die and the memory dies;
a redistribution layer (RDL) containing conductive traces over the front side of the processor die; and
a heat spreading layer or a thermal isolation layer is formed in the RDL, in a backend-of-line (BEOL) structure proximal to the front side of the processor die, or in a front-end-of-line (FEOL) structure proximal to the front side of the processor die.

20. The semiconductor package of claim 18, further comprising:
a heat spreader over the plurality of memory dies;
a laminate substrate supporting the processor die, the first HTC structure, the memory dies, the control dies, and the second HTC structure; and
a flexible circuit interconnect electrically connecting the laminate substrate or the first HTC structure to a circuit layer proximal to the heat spreader with the flexible circuit interconnect configured to provide power and signaling to at least one of the front side of the processor die or the control dies.
